(19) United States
(12) Patent Application Publication
(10) Pub. No.: US 2026/0020456 A1
(43) Pub. Date: Jan. 15, 2026

(54) DISPLAY DEVICE

(71) Applicant: SAMSUNG DISPLAY CO., LTD., YONGIN-SI (KR)

(72) Inventors: JUNYOUNG MIN, Yongin-si (KR); MINJOO KIM, Yongin-si (KR); Hyojoon SONG, Yongin-si (KR); JUNWON CHOI, Yongin-si (KR)

(21) Appl. No.: 19/090,583

(22) Filed: Mar. 26, 2025

(30) Foreign Application Priority Data
Jul. 11, 2024 (KR) 10-2024-0091520

(51) Int. Cl. H10K 59/131

(52) U.S. Cl. CPC H10K 59/131

(57) ABSTRACT

A display device includes a plurality of pixels. A power line is connected to the plurality of pixels. The power line includes a plurality of horizontal power lines extending in a first direction and arranged in a second direction crossing the first direction and a plurality of vertical power lines extending in the second direction and arranged in the first direction. The plurality of vertical power lines cross the plurality of horizontal power lines when viewed from above a plane. The plurality of horizontal power lines is alternately connected to two adjacent vertical power lines of the plurality of vertical power lines.

### CROSS-REFERENCE TO RELATED APPLICATIONS

This application claims priority under 35 U.S.C. § 119 to Korean Patent Application No. 10-2024-0091520, filed on Jul. 11, 2024 in the Korean Intellectual Property Office, the disclosure of which is incorporated by reference in its entirety herein.

### 1. TECHNICAL FIELD

Embodiments of the present disclosure described herein relate to a display device.

### 2. DISCUSSION OF RELATED ART

Numerous different electronic devices include a display device for displaying an image to a user, such as smart phones, digital cameras, notebook computers, car navigation units, smart televisions. The display device generates an image and provides the generated image to the user through a display screen.

The display device includes a plurality of pixels for generating an image. Each of the pixels includes a light emitting element, a plurality of transistors connected to the light emitting element to control an operation of the light emitting element, and at least one capacitor connected to the transistors.

The pixels are connected to a power line and are driven by receiving a drive voltage through the power line. However, the drive voltage may not be stably supplied to the pixels when there is an IR drop, depending on the resistance of the power line. Accordingly, research is being conducted concerning a technology for stably supplying the drive voltage.

### SUMMARY

Embodiments of the present disclosure provide a display device for stably supplying a drive voltage to pixels.

According to an embodiment, a display device includes a plurality of pixels. A power line is connected to the plurality of pixels. The power line includes a plurality of horizontal power lines extending in a first direction and arranged in a second direction crossing the first direction and a plurality of vertical power lines extending in the second direction and arranged in the first direction. The plurality of vertical power lines cross the plurality of horizontal power lines when viewed from above a plane. The plurality of horizontal power lines is alternately connected to two adjacent vertical power lines of the plurality of vertical power lines.

According to an embodiment, a display device includes a plurality of pixels. A power line is connected to the plurality of pixels. The power line includes a plurality of horizontal power lines extending in a first direction and arranged in a second direction crossing the first direction. A plurality of vertical power lines extends in the second direction and is arranged in the first direction. The plurality of vertical power lines crosses the plurality of horizontal power lines when viewed from above a plane. Odd-numbered horizontal power lines of the plurality of horizontal power lines are connected to even-numbered vertical power lines of the plurality of vertical power lines, and even-numbered horizontal power lines of the plurality of horizontal power lines are connected to odd-numbered vertical power lines of the plurality of vertical power lines.

According to an embodiment of the present disclosure, an electronic device for providing an image includes a display device having a plurality of pixels and a power line is connected to the plurality of pixels. The power line includes a plurality of horizontal power lines extending in a first direction and arranged in a second direction crossing the first direction. A plurality of vertical power lines extends in the second direction and is arranged in the first direction. The plurality of vertical power lines crosses the plurality of horizontal power lines when viewed from above a plane. The plurality of horizontal power lines is alternately connected to two adjacent vertical power lines of the plurality of vertical power lines. The plurality of vertical power lines is alternately connected to two adjacent horizontal power lines of the plurality of horizontal power lines.

### BRIEF DESCRIPTION OF THE DRAWINGS

The above and other objects and features of the present disclosure will become apparent by describing in detail non-limiting embodiments thereof with reference to the accompanying drawings.

FIG. 1 is a perspective view of a display device according to an embodiment of the present disclosure.

FIG. 2 is a cross-sectional view of the display device illustrated in FIG. 1 according to an embodiment of the present disclosure.

FIG. 3 is a cross-sectional view of a display panel illustrated in FIG. 2 according to an embodiment of the present disclosure.

FIG. 4 is a block diagram of the display device according to an embodiment of the present disclosure.

FIG. 5 is an equivalent circuit diagram of a pixel illustrated in FIG. 4 according to an embodiment of the present disclosure.

FIG. 6 is a schematic view illustrating a planar configuration of the display panel according to an embodiment of the present disclosure.

FIG. 7 is a schematic cross-sectional view of the pixel illustrated in FIG. 5 according to an embodiment of the present disclosure.

FIG. 8 is an enlarged view of a first area AA1 illustrated in FIG. 7 according to an embodiment of the present disclosure.

FIG. 9 is an enlarged view of a second area AA2 illustrated in FIG. 7 according to an embodiment of the present disclosure.

FIGS. 10A to 10J are views illustrating a planar structure of the pixel in FIG. 5 step by step according to embodiments of the present disclosure.

FIG. 11 is a plan view of the display panel schematically illustrating a first power line, light emitting elements, and pixel circuits according to an embodiment of the present disclosure.

FIG. 12 is a plan view of the display panel schematically illustrating initialization lines, light emitting elements, and pixel circuits according to an embodiment of the present disclosure.

FIG. 13 is an enlarged view of a first horizontal power line connected to a second power bus line and a horizontal initialization line connected to a second initialization bus line in FIGS. 11 and 12 according to an embodiment of the present disclosure.

FIG. 14 is a cross-sectional view taken along line I-I′ illustrated in FIG. 13 according to an embodiment of the present disclosure.

FIGS. 15 to 20 are views illustrating configurations of display panels according to embodiments of the present disclosure.

### DETAILED DESCRIPTION OF EMBODIMENTS

In this specification, when a component (or, an area, a layer, a part, etc.) is referred to as being “on”, “connected to” or “coupled to” another component, this means that the component may be directly on, connected to, or coupled to the other component or a third component may be present therebetween. When a component is referred to as being “directly on”, “directly connected to” or “directly coupled to” another component, no intervening elements may be present.

Identical reference numerals refer to identical components. Additionally, in the drawings, the thicknesses, proportions, and dimensions of components may be exaggerated for effective description.

As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of embodiments of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

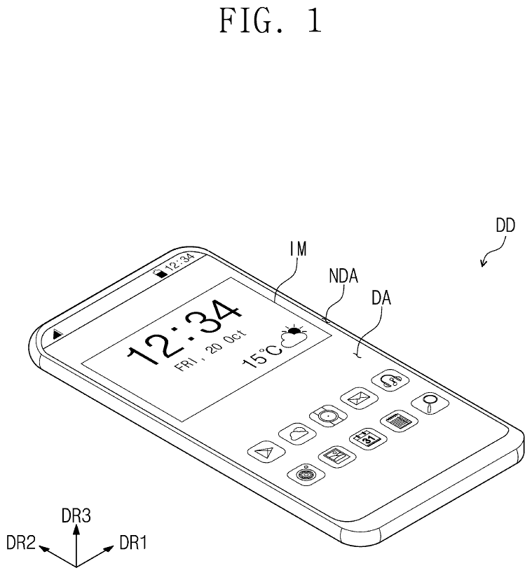

FIG. 1 is a perspective view of a display device according to an embodiment of the present disclosure.

Referring to FIG. 1, the display device DD according to an embodiment of the present disclosure may have relatively short sides extending in a first direction DR1 and relatively long sides extending in a second direction DR2 crossing the first direction DR1. The corners of the display device DD may have a rounded shape. The shape of the display device DD illustrated in FIG. 1 is illustrated as an example, and the display device DD is not necessarily limited to the shape illustrated in FIG. 1 and may vary.

Hereinafter, a direction substantially perpendicular to a plane defined by the first direction DR1 and the second direction DR2 is defined as a third direction DR3. As used herein, the expression “when viewed from above the plane” may mean that it is viewed in the third direction DR3. While the first to third directions DR1, DR2, DR3 are shown as being perpendicular to each other, embodiments of the present disclosure are not necessarily limited thereto and the first to third directions DR1, DR2, DR3 may cross each other at various different angles.

In an embodiment, images IM generated by the display device DD may be provided to a user through the upper surface of the display device DD viewed in the third direction DR3. The upper surface of the display device DD may include a display area DA and a non-display area NDA around the display area DA (e.g., in the first and/or second directions DR1, DR2). The display area DA may display an image, and the non-display area NDA may not display an image. The non-display area NDA may at least partially surround the display area DA (e.g., in a plan view) and may define the border of the display device DD and may be printed in a certain color.

The display device DD is illustrated as a mobile phone. However, embodiments of the present disclosure are not necessarily limited thereto and the display device DD may be used in various electronic devices. For example, in some embodiments the display device DD may be used in large electronic devices such as a television, a monitor, and a billboard. In addition, the display device DD may be used in small and medium-sized electronic devices such as a personal computer, a notebook computer, a car navigation unit, a game machine, a tablet computer, and a camera.

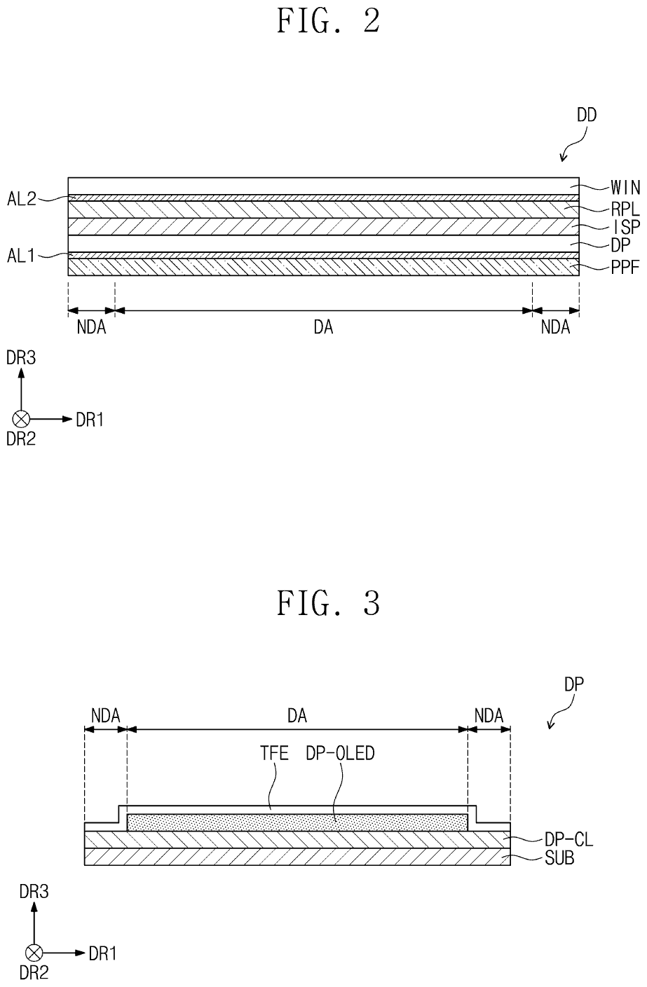

FIG. 2 is a cross-sectional view of the display device illustrated in FIG. 1.

In FIG. 2, a cross-section of the display device DD viewed in the second direction DR2 is illustrated.

Referring to FIG. 2, in an embodiment the display device DD may include a display panel DP, an input sensing part ISP, an anti-reflective layer RPL, a window WIN, a panel protection film PPF, a first adhesive layer AL1, and a second adhesive layer AL2.

The display panel DP according to an embodiment of the present disclosure may be an emissive display panel. For example, in an embodiment the display panel DP may be an organic light emitting display panel or an inorganic light emitting display panel. An emissive layer of the organic light emitting display panel may include an organic luminescent material. An emissive layer of the inorganic light emitting display panel may include quantum dots, quantum rods, and the like. Hereinafter, it will be exemplified that the display panel DP is an organic light emitting display panel for convenience of explanation. However, embodiments of the present disclosure are not necessarily limited thereto.

The input sensing part ISP may be disposed on the display panel DP. In an embodiment, the input sensing part ISP may include a plurality of sensing parts for sensing an external input in a capacitance type. In an embodiment, the input sensing part ISP may be directly manufactured on (e.g., disposed directly thereon in the third direction DR3) the display panel DP when the display device DD is manufactured. However, embodiments of the present disclosure are not necessarily limited thereto. For example, in some embodiments the input sensing part ISP may be manufactured as a panel separate from the display panel DP and may be attached to the display panel DP by an adhesive layer.

The anti-reflective layer RPL may be disposed on the input sensing part ISP. In an embodiment, the anti-reflective layer RPL may be directly manufactured on (e.g., disposed directly thereon in the third direction DR3) the input sensing part ISP when the display device DD is manufactured. However, embodiments of the present disclosure are not necessarily limited thereto. For example, in some embodiments the anti-reflective layer RPL may be manufactured as a separate panel and may be attached to the input sensing part ISP by an adhesive layer.

The anti-reflective layer RPL may be a film for preventing reflection of external light. The anti-reflective layer RPL may decrease the reflectance of external light incident towards the display panel DP from above the display device DD. The external light may not be visible to the user due to the anti-reflective layer RPL.

When external light travelling toward the display panel DP is reflected from the display panel DP and provided back to the user, the user may visually recognize the external light, such as in a mirror. In an embodiment, to prevent such a phenomenon, the anti-reflective layer RPL may include a plurality of color filters that display the same colors as those of pixels of the display panel DP.

The color filters may filter external light into the same colors as those of the pixels. In this embodiment, the external light may not be visible to the user. However, embodiments of the present disclosure are not necessarily limited thereto. For example, in some embodiments the anti-reflective layer RPL may include a phase retarder and/or a polarizer to decrease the reflectance of the external light.

The window WIN may be disposed on the anti-reflective layer RPL (e.g., in the third direction DR3). The window WIN may protect the display panel DP, the input sensing part ISP, and the anti-reflective layer RPL from external scratches and impacts.

The panel protection film PPF may be disposed under the display panel DP (e.g., in a direction opposite to the third direction DR3). The panel protection film PPF may protect a lower portion of the display panel DP. In an embodiment, the panel protection film PPF may include a flexible plastic material such as polyethylene terephthalate (PET).

In an embodiment, the first adhesive layer AL1 may be disposed between the display panel DP and the panel protection film PPF (e.g., in the third direction DR3), and the display panel DP and the panel protection film PPF may be bonded to each other by the first adhesive layer AL1. The second adhesive layer AL2 may be disposed between the window WIN and the anti-reflective layer RPL (e.g., in the third direction DR3), and the window WIN and the anti-reflective layer RPL may be bonded to each other by the second adhesive layer AL2.

FIG. 3 is a cross-sectional view of the display panel illustrated in FIG. 2.

In FIG. 3, a cross-section of the display panel DP viewed in the second direction DR2 is illustrated.

Referring to FIG. 3, in an embodiment the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA (e.g., in the first and/or second directions DR1, DR2). In an embodiment, the substrate SUB may include glass or may include a flexible plastic material such as polyimide (PI). The display element layer DP-OLED may be disposed on the display area DA.

A plurality of pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matter, such as dust, debris, etc.

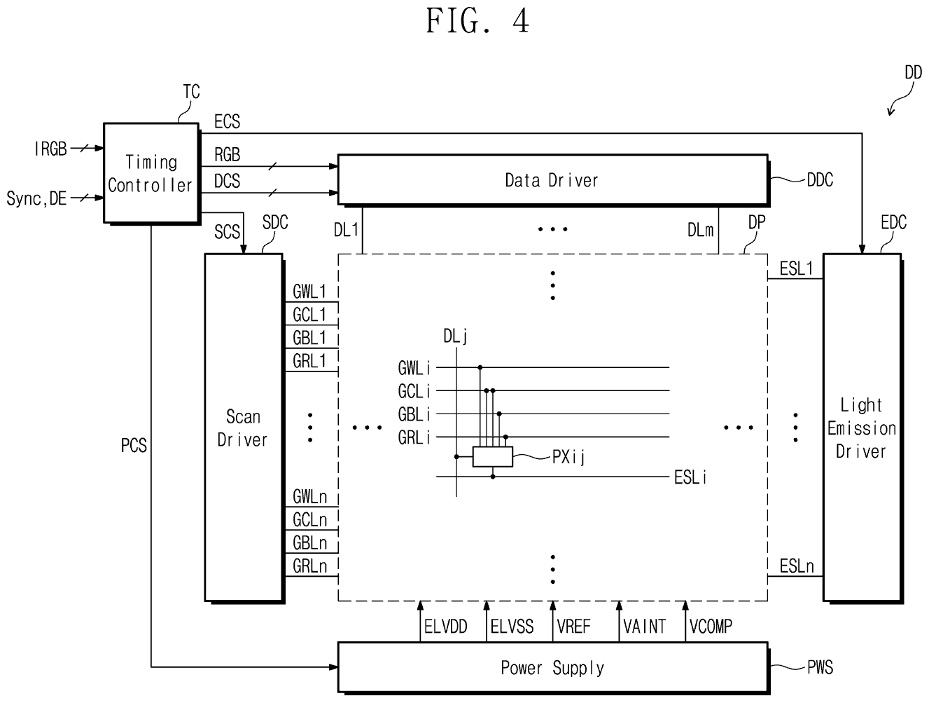

FIG. 4 is a block diagram of the display device according to an embodiment of the present disclosure.

Referring to FIG. 4, in an embodiment the display device DD may include the display panel DP, a panel driver SDC, EDC, and DDC, a power supply PWS, and a timing controller TC. The panel driver SDC, EDC, and DDC may include a scan driver SDC, a light emission driver EDC, and a data driver DDC.

In an embodiment, the display panel DP may be an emissive display panel. The emissive display panel may include an organic light emitting display panel, an inorganic light emitting display panel, or a quantum-dot light emitting display panel. Hereinafter, it will be exemplified that the display panel of the present disclosure is an organic light emitting display panel for economy of description.

In an embodiment, the display panel DP may include a plurality of scan lines GWL1 to GWLn, GCL1 to GCLn, GBL1 to GBLn, and GRL1 to GRLn, a plurality of emission lines ESL1 to ESLn, and a plurality of data lines DL1 to DLm. “m” and “n” may be natural numbers greater than 1.

The display panel DP may include a plurality of pixels PXij connected to the scan lines GWL1 to GWLn, GCL1 to GCLn, GBL1 to GBLn, and GRL1 to GRLn, the emission lines ESL1 to ESLn, and the data lines DL1 to DLm. For example, one pixel PXij disposed on the i-th horizontal line (e.g., the i-th pixel row) and the j-th vertical line (or, the j-th pixel column) is illustrated in FIG. 4. However, the plurality of pixels PXij may be substantially disposed in the display panel DP. “i” and “j” may be natural numbers.

The pixel PXij may be connected to the i-th first scan line (e.g., a write scan line) GWLi, the i-th second scan line (e.g., an initialization scan line) GCLi, the i-th third scan line (e.g., a compensation scan line) GBLi, the i-th fourth scan line (e.g., a reset scan line) GRLi, the j-th data line DLj, and the i-th emission line ESLi.

The pixel PXij may include a light emitting element, a plurality of transistors, and a plurality of capacitors. The pixel PXij may receive a first power supply voltage ELVDD, a second power supply voltage ELVSS, a third power supply voltage (e.g., a reference voltage) VREF, a fourth power supply voltage (e.g., an initialization voltage) VAINT, and a fifth power supply voltage (e.g., a compensation voltage) VCOMP through the power supply PWS.

The light emitting element may be driven by the first power supply voltage ELVDD and the second power supply voltage ELVSS. Voltage values of the first power supply voltage ELVDD and the second power supply voltage ELVSS may be set such that electric current flows through the light emitting element and the light emitting element emits light. For example, in an embodiment the first power supply voltage ELVDD may be set to a voltage value higher than the second power supply voltage ELVSS. The first power supply voltage ELVDD and the second power supply voltage ELVSS may be defined as a drive voltage.

The third power supply voltage VREF may be a voltage for initializing a gate of a drive transistor of the pixel PXij. The fourth power supply voltage VAINT may be a voltage for initializing a cathode of the light emitting element of the pixel PXij.

The fifth power supply voltage VCOMP may provide a predetermined current to the drive transistor when the threshold voltage of the drive transistor is compensated for. For example, in an embodiment the fifth power supply voltage VCOMP may be set to a voltage value equal to the first power supply voltage ELVDD. However, embodiments of the present disclosure are not necessarily limited thereto and the fifth power supply voltage VCOMP may be set to a voltage value different from the first power supply voltage ELVDD.

The scan driver SDC may receive a first control signal SCS from the timing controller TC and may generate a plurality of scan signals in response to the first control signal SCS. The scan driver SDC may provide the scan signals to the first scan lines GWL1 to GWLn, the second scan lines GCL1 to GCLn, the third scan lines GBL1 to GBLn, and the fourth scan lines GRL1 to GRLn.

In FIG. 4, for convenience of description, the scan driver SDC is illustrated as a single component. However, embodiments of the present disclosure are not necessarily limited thereto. For example, in some embodiments the display device DD may include a plurality of scan drivers for providing the scan signals to the first scan lines GWL1 to GWLn, the second scan lines GCL1 to GCLn, the third scan lines GBL1 to GBLn, and the fourth scan lines GRL1 to GRLn.

The light emission driver EDC may receive a second control signal ECS from the timing controller TC and may generate a plurality of emission signals in response to the second control signal ECS. The light emission driver EDC may provide the emission signals to the emission lines ESL1 to ESLn.

The data driver DDC may receive a third control signal DCS and a plurality of pieces of image data RGB from the timing controller TC. In an embodiment, the data driver DDC may convert the plurality of pieces of image data RGB in a digital format into a plurality of data signals (e.g., data voltages) in an analog format. The data driver DDC may provide the data signals to the data lines DL1 to DLm in response to the third control signal DCS.

In an embodiment, in response to a fourth control signal PCS provided from the timing controller TC, the power supply PWS may generate the first power supply voltage ELVDD, the second power supply voltage ELVSS, the third power supply voltage VREF, the fourth power supply voltage VAINT, and the fifth power supply voltage VCOMP for driving the pixel PXij.

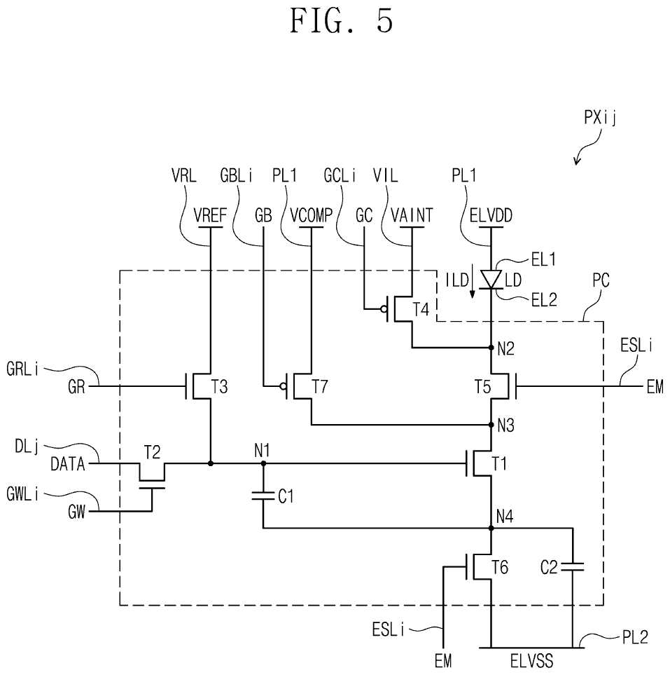

In an embodiment, the power supply PWS may provide the first power supply voltage ELVDD, the second power supply voltage ELVSS, the third power supply voltage VREF, the fourth power supply voltage VAINT, and the fifth power supply voltage VCOMP to the display panel DP. The first power supply voltage ELVDD, the second power supply voltage ELVSS, the third power supply voltage VREF, the fourth power supply voltage VAINT, and the fifth power supply voltage VCOMP may be provided to the pixel PXij through power lines (illustrated in FIG. 5) that are connected to the pixel PXij.

In an embodiment, the timing controller TC may generate the first control signal SCS, the second control signal ECS, the third control signal DCS, and the fourth control signal PCS, based on a plurality of pieces of input image data IRGB, a plurality of synchronization signals Sync (e.g., a vertical synchronization signal and a horizontal synchronization signal), a data enable signal DE, and a clock signal.

In an embodiment, the first control signal SCS may be provided to the scan driver SDC, and the second control signal ECS may be provided to the light emission driver EDC. The third control signal DCS may be provided to the data driver DDC, and the fourth control signal PCS may be provided to the power supply PWS.

The timing controller TC may generate the image data RGB (e.g., frame data) by rearranging the input image data IRGB in correspondence to the arrangement of the pixels PXij in the display panel DP.

FIG. 5 is an equivalent circuit diagram of the pixel illustrated in FIG. 4 according to an embodiment of the present disclosure.

An equivalent circuit diagram of the pixel PXij connected to the i-th first scan line GWLi and the j-th data line DLj is illustrated in FIG. 5.

Referring to FIG. 5, the pixel PXij may be connected to the i-th first scan line GWLi, the i-th second scan line GCLi, the i-th third scan line GBLi, the i-th fourth scan line GRLi, the j-th data line DLj (hereinafter, referred to as the data line), the i-th emission line ESLi (hereinafter, referred to as the emission line), and a plurality of power lines PL1, PL2, VIL, and VRL.

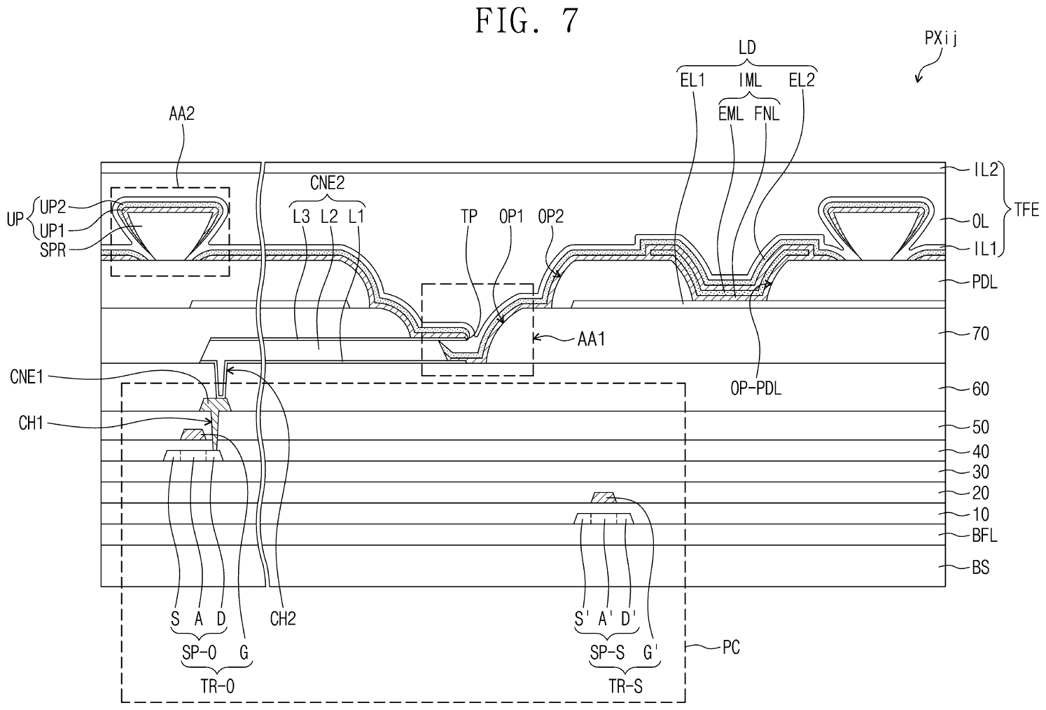

The pixel PXij may include a light emitting element LD and a pixel circuit PC. The light emitting element LD may be connected between the first power line PL1 and the pixel circuit PC. The light emitting element LD may include a first electrode EL1 (e.g., an anode), a second electrode EL2 (e.g., a cathode), and an emissive layer (illustrated in FIG. 7) between the first electrode EL1 and the second electrode EL2. The first power supply voltage ELVDD may be applied to the first electrode EL1, and the second power supply voltage ELVSS may be applied to the second electrode EL2.

The pixel circuit PC may be connected to the i-th first scan line GWLi, the i-th second scan line GCLi, the i-th third scan line GBLi, the i-th fourth scan line GRLi, the data line DLj, the emission line ESLi, and the power lines PL1, PL2, VIL, and VRL The pixel circuit PC may include first to seventh transistors T1 to T7, a first capacitor C1, and a second capacitor C2.

Hereinafter, the i-th first scan line GWLi, the i-th second scan line GCLi, the i-th third scan line GBLi, and the i-th fourth scan line GRLi are referred to as the write scan line GWLi, the initialization scan line GCLi, the compensation scan line GBLi, and the reset scan line GRLi, respectively.

In an embodiment, the first, second, third, fifth, and sixth transistors T1, T2, T3, T5, and T6 may be N-type transistors. The fourth transistor T4 and the seventh transistor T7 may be P-type transistors.

Each of the first to seventh transistors T1 to T7 may include a source, a drain, and a gate. Hereinafter, in FIG. 5, for convenience of explanation, one of the source and the drain is defined as a first electrode, and the other one of the source and the drain is defined as a second electrode.

The first transistor T1 may be switched by a voltage of a first node N1. The first transistor T1 may be connected to the second electrode EL2 of the light emitting element LD through the fifth transistor T5. The first transistor T1 may be connected to the second power line PL2 through the sixth transistor T6.

The first transistor T1 may include a gate connected to the first node N1, a first electrode connected to a third node N3, and a second electrode connected to a fourth node N4. The first transistor T1 may be defined as a drive transistor.

In an embodiment, depending on the voltage of the first node N1, the first transistor T1 may control a drive current ILD flowing from the first power line PL1 to the second power line PL2 via the light emitting element LD. For this operation, the first power supply voltage ELVDD may be set to a voltage having a higher level than the second power supply voltage ELVSS.

The second transistor T2 may be connected between the first node N1 and the data line DLj and may be switched by a write scan signal GW. The second transistor T2 may include a gate connected to the write scan line GWLi, a first electrode connected to the data line DLj, and a second electrode connected to the first node N1. The data line DLj may receive a data signal DATA.

In an embodiment, the second transistor T2 may be turned on in response to the write scan signal GW provided through the write scan line GWLi and may provide the data signal DATA to the first node N1. The second transistor T2 may be turned on by the write scan signal GW and may electrically connect the data line DLj and the first node N1.

The third transistor T3 may be connected between the first node N1 and the reference line VRL. The third transistor T3 may include a gate connected to the reset scan line GRLi, a first electrode connected to the reference line VRL, and a second electrode connected to the first node N1.

The reference line VRL may receive the reference voltage VREF, and the reset scan line GRLi may receive a reset scan signal GR. In an embodiment, the third transistor T3 may be turned on in response to the reset scan signal GR and may provide the reference voltage VREF to the first node N1.

The fourth transistor T4 may be connected between the initialization line VIL and a second node N2. The fourth transistor T4 may include a gate connected to the initialization scan line GCLi, a first electrode connected to the initialization line VIL, and a second electrode connected to the second node N2.

The initialization scan line GCLi may receive an initialization scan signal GC, and the initialization line VIL may receive the initialization voltage VAINT. In an embodiment, the fourth transistor T4 may be turned on in response to the initialization scan signal GC and may provide the initialization voltage VAINT to the second node N2 connected to the second electrode EL2 of the light emitting element LD. The second electrode EL2 of the light emitting element LD may be initialized by the initialization voltage VAINT.

The fifth transistor T5 may be connected between the first transistor T1 and the light emitting element LD. The fifth transistor T5 may include a gate connected to the emission line ESLi, a first electrode connected to the second node N2, and a second electrode connected to the third node N3.

In an embodiment, the emission line ESLi may receive an emission signal EM. The fifth transistor T5 may be turned on in response to the emission signal EM and may electrically connect the light emitting element LD and the first transistor T1.

The sixth transistor T6 may be connected between the second power line PL2 and the fourth node N4. The sixth transistor T6 may include a gate connected to the emission line ESLi, a first electrode connected to the fourth node N4, and a second electrode connected to the second power line PL2.

The second power line PL2 may receive the second power supply voltage ELVSS. In an embodiment, the sixth transistor T6 may be turned on in response to the emission signal EM and may electrically connect the first transistor T1 and the second power line PL2.

The seventh transistor T7 may be connected between the first power line PL1 and the third node N3. The seventh transistor T7 may include a gate connected to the compensation scan line GBLi, a first electrode connected to the first power line PL1, and a second electrode connected to the third node N3.

The compensation scan line GBLi may receive a compensation scan signal GB, and the first power line PL1 may receive the compensation voltage VCOMP. In an embodiment, the seventh transistor T7 may be turned on in response to the compensation scan signal GB and may provide the compensation voltage VCOMP to the third node N3, and the threshold voltage of the first transistor T1 may be compensated for during a compensation period.

The first capacitor C1 may be connected between the first node N1 and the fourth node N4. The first capacitor C1 may store charges corresponding to a difference in voltage between the first node N1 and the fourth node N4. The first capacitor C1 may be defined as a storage capacitor.

The first capacitor C1 may include a first capacitor electrode connected to the first node N1 and a second capacitor electrode connected to the fourth node N4. The first capacitor electrode may be connected to the gate of the first transistor T1, and the second capacitor electrode may be connected to the second electrode of the first transistor T1.

The second capacitor C2 may be connected between the fourth node N4 and the second power line PL2. The second capacitor C2 may include a third capacitor electrode connected to the fourth node N4 and a fourth capacitor electrode connected to the second power line PL2. The second capacitor C2 may store charges corresponding to a difference in voltage between the second power supply voltage ELVSS and the fourth node N4. The second capacitor C2 may be defined as a hold capacitor.

The light emitting element LD may be connected with the pixel circuit PC through the second node N2. The first electrode EL1 of the light emitting element LD may be connected to the first power line PL1, and the second electrode EL2 of the light emitting element LD may be connected to the second node N2. The light emitting element LD may be connected with the pixel circuit PC through the second electrode EL2.

A connection node at which the light emitting element LD and the pixel circuit PC are connected may be the second node N2, and the second node N2 may correspond to a connection node between the first electrode of the fifth transistor T5 and the second electrode EL2 of the light emitting element LD. Accordingly, the potential of the second node N2 may substantially correspond to the potential of the second electrode EL2 of the light emitting element LD.

The first power supply voltage ELVDD, which is a constant voltage, may be applied to the first electrode EL1 of the light emitting element LD, and the second electrode EL2 of the light emitting element LD may be connected to the first transistor T1 through the fifth transistor T5. In an embodiment, due to the above-described connecting structure, the potential of the fourth node N4 corresponding to the source of the first transistor T1, which is a drive transistor, may not be directly affected by characteristics of the light emitting element LD.

In this embodiment, an influence on the transistors constituting the pixel circuit PC may be reduced even though the light emitting element LD is degraded. For example, an influence on the gate-source voltage Vgs of the drive transistor due to the degradation of the light emitting element LD may be reduced. Accordingly, even though the light emitting element LD is degraded, the amount of change in the drive current may be reduced. Thus, an after-image defect of the display panel DP depending on an increase in usage time may be reduced, and the lifespan of the pixel PXij may be increased.

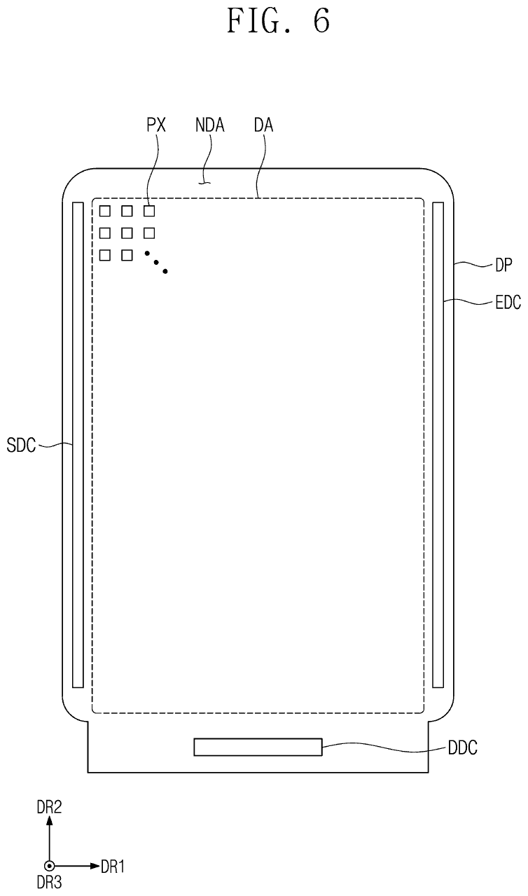

FIG. 6 is a schematic view illustrating a planar configuration of the display panel according to an embodiment of the present disclosure.

In FIG. 6, some components (e.g., lines) of the display panel DP are omitted for convenience of description.

Referring to FIG. 6, in an embodiment the display panel DP may extend longer in the second direction DR2 than in the first direction DR1. The display panel DP may include a display area DA and a non-display area NDA around the display area DA. The non-display area NDA may at least partially surround the display area DA (e.g., in a plan view). The display area DA may include a plurality of pixels PX. Each of the pixels PX may correspond to the pixel PXij illustrated in FIG. 4.

In this embodiment, the scan driver SDC, the light emission driver EDC, and the data driver DDC may be mounted on the display panel DP. The scan driver SDC, the light emission driver EDC, and the data driver DDC may be disposed on the non-display area NDA. When viewed from above the plane, the data driver DDC may be disposed on the non-display area NDA adjacent to the lower side of the display panel DP (e.g., in the second direction DR2). The scan driver SDC and the light emission driver EDC may overlap the non-display areas NDA adjacent to the opposite sides of the display area DA that face away from each other in the first direction DR1.

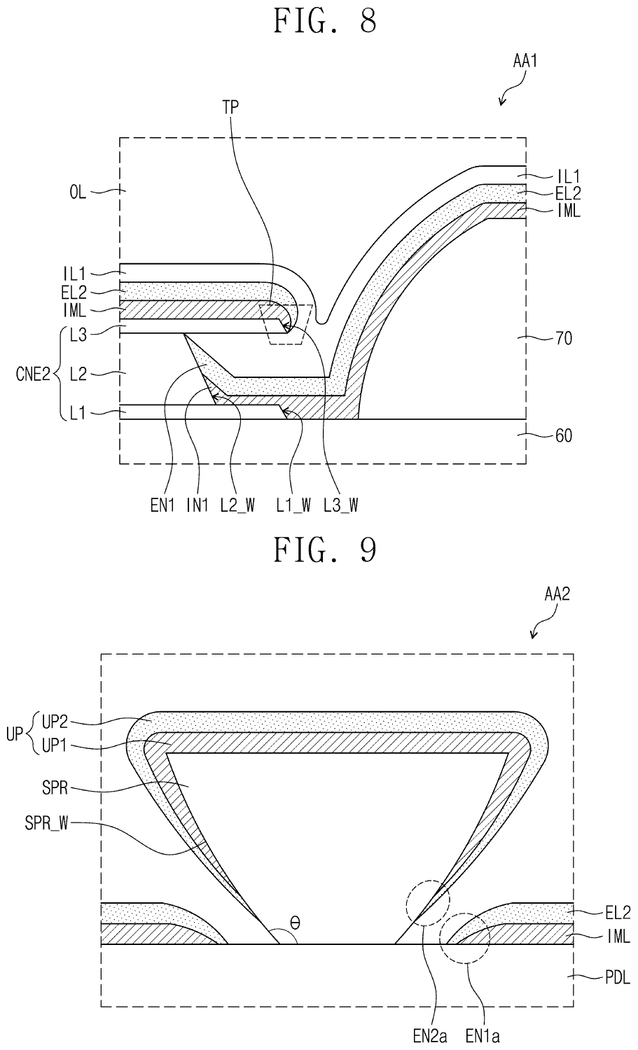

FIG. 7 is a schematic cross-sectional view of the pixel illustrated in FIG. 5. FIG. 8 is an enlarged view of a first area AA1 illustrated in FIG. 7. FIG. 9 is an enlarged view of a second area AA2 illustrated in FIG. 7.

Referring to FIG. 7, the pixel circuit PC may be disposed on a base layer BS. The base layer BS may be a rigid substrate or may be a flexible substrate capable of being bent, folded, or rolled. In an embodiment, the base layer BS may be a glass substrate, a metal substrate, or a polymer substrate.

In an embodiment, the pixel circuit PC may include a silicon transistor TR-S and an oxide transistor TR-O. For example, the silicon transistor TR-S may be the fourth transistor T4 and the seventh transistor T7 described above. The oxide transistor TR-O may be the first, second, third, fifth, and sixth transistors T1, T2, T3, T5, and T6 described above.

A buffer layer BFL may be disposed on the base layer BS (e.g., disposed directly thereon in the third direction DR3). The buffer layer BFL may be an inorganic layer. A semiconductor layer SP-S of the silicon transistor TR-S may be disposed on the buffer layer BFL (e.g., disposed directly thereon in the third direction DR3). The semiconductor layer SP-S may include poly silicon. However, embodiments of the present disclosure are not necessarily limited thereto. For example, the semiconductor layer SP-S may include amorphous silicon.

The semiconductor layer SP-S may be doped with an N-type dopant or a P-type dopant. The semiconductor layer SP-S may include highly-doped areas and a lightly-doped area. The highly-doped areas may have a higher conductivity than the lightly-doped area and may substantially serve as a source electrode and a drain electrode of the silicon transistor TR-S. The lightly-doped area may substantially correspond to an active (e.g., a channel) area of the silicon transistor TR-S.

The semiconductor layer SP-S may include a source area S′, a channel area A′, and a drain area D′. The channel area A′ may be disposed between the source area S′ and the drain area D′. A first insulating layer 10 may be disposed on the buffer layer BFL (e.g., disposed directly thereon in the third direction DR3) to cover the semiconductor layer SP-S. A gate electrode G′ of the silicon transistor TR-S may be disposed on the first insulating layer 10 (e.g., disposed directly thereon in the third direction DR3). The gate electrode G′ may overlap the channel area A′ (e.g., in the third direction DR3).

A second insulating layer 20 may be disposed on (e.g., disposed directly thereon) the gate electrode G′. The second insulating layer 20 may be disposed on the first insulating layer 10 (e.g., disposed directly thereon in the third direction DR3) to cover the gate electrode G′. A third insulating layer 30 may be disposed on the second insulating layer 20 (e.g., disposed directly thereon in the third direction DR3).

A semiconductor layer SP-0 of the oxide transistor TR-O may be disposed on the third insulating layer 30 (e.g., disposed directly thereon in the third direction DR3). The semiconductor layer SP-0 may include an oxide semiconductor formed of metal oxide. The oxide semiconductor may include a crystalline or amorphous oxide semiconductor.

The semiconductor layer SP-0 may include a plurality of areas distinguished from each other depending on whether metal oxide is reduced or not. An area where the metal oxide is reduced (hereinafter, referred to as the reduced area) may have a higher conductivity than an area where the metal oxide is not reduced (hereinafter, referred to as the non-reduced area). The reduced area may substantially serve as a source electrode or a drain electrode of the oxide transistor TR-O. The non-reduced area may substantially correspond to an active (e.g., channel) area of the oxide transistor TR-O.

In an embodiment, the semiconductor layer SP-0 may include a source area S, a channel area A, and a drain area D. The channel area A may be disposed between the source area S and the drain area D. A fourth insulating layer 40 may be disposed on the third insulating layer 30 (e.g., disposed directly thereon in the third direction DR3) to cover the semiconductor layer SP-0. A gate electrode G of the oxide transistor TR-O may be disposed on the fourth insulating layer 40 (e.g., disposed directly thereon in the third direction DR3). The gate electrode G may overlap the channel area A (e.g., in the third direction DR3).

A fifth insulating layer 50 may be disposed on the fourth insulating layer 40 (e.g., disposed directly thereon in the third direction DR3) to cover the gate electrode G. The buffer layer BFL and the first to fifth insulating layers 10 to 50 may include an inorganic layer.

A first connecting electrode CNE1 may be disposed on the fifth insulating layer 50 (e.g., disposed directly thereon in the third direction DR3). In an embodiment, the first connecting electrode CNE1 may be connected to the drain area D of the semiconductor layer SP-0 through a first contact hole CH1 defined in the fourth insulating layer 40 and the fifth insulating layer 50.

A sixth insulating layer 60 may be disposed on the fifth insulating layer 50 (e.g., disposed directly thereon in the third direction DR3) to cover the first connecting electrode CNE1. A second connecting electrode CNE2 may be disposed on the sixth insulating layer 60 (e.g., disposed directly thereon in the third direction DR3). In an embodiment, the second connecting electrode CNE2 may be connected to the first connecting electrode CNE1 through a second contact hole CH2 defined in the sixth insulating layer 60.

The second connecting electrode CNE2 may be connected to the light emitting element LD. In an embodiment, the first connecting electrode CNE1 and the second connecting electrode CNE2 may electrically connect the oxide transistor TR-O and the light emitting element LD to each other. For example, the oxide transistor TR-O illustrated in FIG. 7 may be the fifth transistor T5 illustrated in FIG. 5.

A seventh insulating layer 70 may be disposed on the sixth insulating layer 60 (e.g., disposed directly thereon in the third direction DR3) and the second connecting electrode CNE2. The sixth insulating layer 60 and the seventh insulating layer 70 may include an organic layer.

The seventh insulating layer 70 may have a first opening OP1 defined therein to expose a portion of the second connecting electrode CNE2. The portion of the second connecting electrode CNE2 exposed from the seventh insulating layer 70 may be electrically connected to the light emitting element LD.

A pixel defining layer PDL may be disposed on the seventh insulating layer 70 (e.g., disposed directly thereon in the third direction DR3). The pixel defining layer PDL may be an organic layer. The pixel defining layer PDL may have a property of absorbing light. For example, in an embodiment the pixel defining layer PDL may be black in color. The pixel defining layer PDL may be a light blocking pattern having light blocking characteristics.

A second opening OP2 that overlaps the first opening OP1 (e.g., in the third direction DR3) and has a larger area than the first opening OP1 may be defined in the pixel defining layer PDL. In addition, a light emitting opening OP-PDL that exposes a portion of the first electrode EL1 may be defined in the pixel defining layer PDL. Components of the light emitting element LD may be disposed in the light emitting opening OP-PDL to overlap one another (e.g., in the third direction DR3), and the light emitting opening OP-PDL may be an area where light emitted by the light emitting element LD is substantially displayed.

In an embodiment, the light emitting element LD may include the first electrode EL1, an intermediate layer IML, and the second electrode EL2. The first electrode EL1 and the second electrode EL2 may be the first electrode EL1 and the second electrode EL2 described with reference to FIG. 5. Accordingly, the first electrode EL1 may be connected to the first power line PL1 described above and may receive the first power supply voltage ELVDD.

The first electrode EL1 may be disposed on the seventh insulating layer 70 (e.g., disposed directly thereon in the third direction DR3), and the pixel defining layer PDL may be disposed on (e.g., disposed directly thereon) the first electrode EL1. The second electrode EL2 may be disposed over the first electrode EL1, and the intermediate layer IML may be disposed between the first electrode EL1 and the second electrode EL2 (e.g., in the third direction DR3). In an embodiment, the intermediate layer IML may include an emissive layer EML and a functional layer FNL.

The light emitting element LD may include the intermediate layer IML having various structures and is not necessarily limited to any one embodiment. For example, the functional layer FNL may include a plurality of layers or may include two or more layers spaced apart from each other with the emissive layer EML therebetween (e.g., in the third direction DR3).

In an embodiment, the emissive layer EML may include an organic luminescent material. Alternatively, the emissive layer EML may include an inorganic luminescent material or may include a mixed layer of an organic luminescent material and an inorganic luminescent material. In some embodiments, the emissive layer EML may generate one of blue light, red light, and green light. However, embodiments of the present disclosure are not necessarily limited thereto.

The functional layer FNL may be disposed between the first electrode EL1 and the second electrode EL2 (e.g., in the third direction DR3). For example, in an embodiment the functional layer FNL may be disposed between the first electrode EL1 and the emissive layer EML (e.g., in the third direction DR3) and between the second electrode EL2 and the emissive layer EML (e.g., in the third direction DR3). The emissive layer EML may be disposed in the light emitting opening OP-PDL and may extend to a portion adjacent to the light emitting opening OP-PDL.

The functional layer FNL may control the movement of charges between the first electrode and the second electrode. In an embodiment, the functional layer FNL may include a hole injection/transport material and/or an electron injection/transport material. For example, the functional layer FNL may include at least one of an electron blocking layer, a hole transport layer, a hole injection layer, a hole blocking layer, an electron transport layer, an electron injection layer, and a charge generation layer.

The second electrode EL2 may be disposed on the intermediate layer IML (e.g., in the third direction DR3). The second electrode EL2 may extend towards the second opening OP2 and the first opening OP1 and may be connected to the second connecting electrode CNE2. For example, in an embodiment the second electrode EL2 may be electrically connected with the oxide transistor TR-O (e.g., the fifth transistor T5) through the second connecting electrode CNE2 and the first connecting electrode CNE1.

Referring to FIGS. 7 and 8, in an embodiment the second connecting electrode CNE2 may have a three-layer structure. The second connecting line CNE2 may include a first layer L1, a second layer L2, and a third layer L3 sequentially stacked one above another in the upper direction (e.g., in the third direction DR3). The second layer L2 may include a material different from those of the first layer L1 and the third layer L3. In an embodiment, the second layer L2 may have a greater thickness (e.g., length in the third direction DR3) than the first layer L1 and the third layer L3. The second layer L2 may include a highly conductive material.

The first layer L1 may include a material having a lower etch rate than the second layer L2. In an embodiment, the first layer L1 may include titanium (Ti), and the second layer L2 may include aluminum (A1). In this embodiment, a side surface L1_W of the first layer L1 may be defined outward of a side surface L2_W of the second layer L2.

The third layer L3 may include a material having a lower etch rate than the second layer L2. In an embodiment, the third layer L3 may include titanium (Ti). In this embodiment, a side surface L3_W of the third layer L3 may be defined outward of the side surface L2_W of the second layer L2.

The side surface L1_W of the first layer L1 and the side surface L3_W of the third layer L3 may protrude outwardly with respect to the side surface L2_W of the second layer L2. Furthermore, the side surface L2_W of the second layer L2 may be recessed inwardly with respect to the side surface L1_W of the first layer L1 and the side surface L3_W of the third layer L3. Due to the above-described configuration, the second connecting electrode CNE2 may have an undercut shape. In addition, a tip portion TP of the second connecting electrode CNE2 may be defined by the portion of the third layer L3 that protrudes outwardly with respect to the second layer L2.

One side of the second connecting electrode CNE2 may be exposed by the first opening OP1. For example, at least a portion of the tip portion TP and at least a portion of the second side surface L2_W may be exposed by the first opening OP1.

In an embodiment, the intermediate layer IML may be disposed on the pixel defining layer PDL. The intermediate layer IML may also be disposed on a portion of the seventh insulating layer 70 exposed by the second opening OP2 of the pixel defining layer PDL. In addition, the intermediate layer IML may also be disposed on a portion of the second connecting electrode CNE2 exposed by the first opening OP1 of the seventh insulating layer 70. The intermediate layer IML disposed on the portion of the seventh insulating layer 70 and the portion of the second connecting electrode CNE2 may be the functional layer FNL. As illustrated in FIG. 8, the intermediate layer IML may include one end IN1 disposed along the upper surface of the sixth insulating layer 60.

In an embodiment, the second electrode EL2 disposed on the intermediate layer IML may also be disposed on a portion of the seventh insulating layer 70 exposed by the second opening OP2 of the pixel defining layer PDL. In addition, the second electrode EL2 may also be disposed on a portion of the second connecting electrode CNE2 exposed by the first opening OP1 of the seventh insulating layer 70. The second electrode EL2 may include one end EN1 disposed along the upper surface of the sixth insulating layer 60.

In an embodiment, the one end EN1 of the second electrode EL2 may be disposed along the side surface of the second layer L2 and may make direct contact with the side surface L2_W of the second layer L2. Accordingly, the second electrode EL2 may be connected to (e.g., directly connected thereto) the second layer L2. Thus, the light emitting element LD may be electrically connected with the oxide transistor TR-O through the second connecting electrode CNE2.

A separator SPR may be disposed on the pixel defining layer PDL (e.g., disposed directly thereon in the third direction DR3). In an embodiment, the second electrode EL2 and the intermediate layer IML may be commonly formed in a plurality of pixels by deposition through an open mask. In this embodiment, the second electrode EL2 and the intermediate layer IML may be divided by the separator SPR. Accordingly, the second electrode EL2 and the intermediate layer IML may be electrically independent for each of adjacent pixels.

Referring to FIGS. 7 and 9, the separator SPR may include an organic insulating material. In an embodiment, the separator SPR may have an inverted tapered shape. For example, the angle θ (hereinafter, referred to as the taper angle) formed by a side surface SPR_W of the separator SPR with respect to the upper surface of the pixel defining layer PDL may be an obtuse angle. However, embodiments of the present disclosure are not necessarily limited thereto and the taper angle θ may be set in various ways as long as the separator SPR is capable of electrically disconnecting the second electrode EL2 for each pixel.

A dummy layer UP may be disposed on the separator SPR (e.g., disposed directly thereon in the third direction DR3). In an embodiment, the dummy layer UP may include a first dummy layer UP1 disposed on the separator SPR and a second dummy layer UP2 disposed on the first dummy layer UP1. In an embodiment, the first dummy layer UP1 may be formed through the same process as the intermediate layer IML and may include the same material as the intermediate layer IML. The second dummy layer UP2 may be formed through the same process as the second electrode EL2 and may include the same material as the second electrode EL2.

As illustrated in FIG. 9, in an embodiment, the second electrode EL2 may include a first end portion ENla, and the second dummy layer UP2 may include a second end portion EN2a. The first end portion ENla may be spaced apart from the separator SPR and may be disposed on the pixel defining layer PDL (e.g., disposed directly thereon in the third direction DR3). The second end portion EN2a may be separated from the first end portion ENla and may be disposed on (e.g., disposed directly thereon) the side surface SPR_W of the separator SPR.

According to an embodiment of the present disclosure, even though there is no separate patterning process for the second electrode EL2 or the intermediate layer IML, the second electrode EL2 or the intermediate layer IML may not be formed on a lower portion of the side surface SPR_W of the separator SPR, and thus the second electrode EL2 or the intermediate layer IML may be divided for each pixel. However, embodiments of the present disclosure are not necessarily limited thereto and as long as the second electrode EL2 or the intermediate layer IML is capable of being electrically disconnected between adjacent pixels PX, the shape of the separator SPR may be modified in various ways.

Referring to FIG. 7, the thin film encapsulation layer TFE may be disposed on the display element layer DP-OLED. The thin film encapsulation layer TFE may cover the light emitting element LD and the separator SPR. In an embodiment, the thin film encapsulation layer TFE may include a first inorganic layer IL1, an organic layer OL, and a second inorganic layer IL2 sequentially stacked one above another (e.g., in the third direction DR3). However, embodiments of the present disclosure are not necessarily limited thereto.

The first inorganic layer IL1 and the second inorganic layer IL2 may include an inorganic insulating layer and may protect the pixel PXij from moisture/oxygen. The organic layer OL may include an organic insulating layer and may protect the pixel PXij from foreign matter such as dust particles.

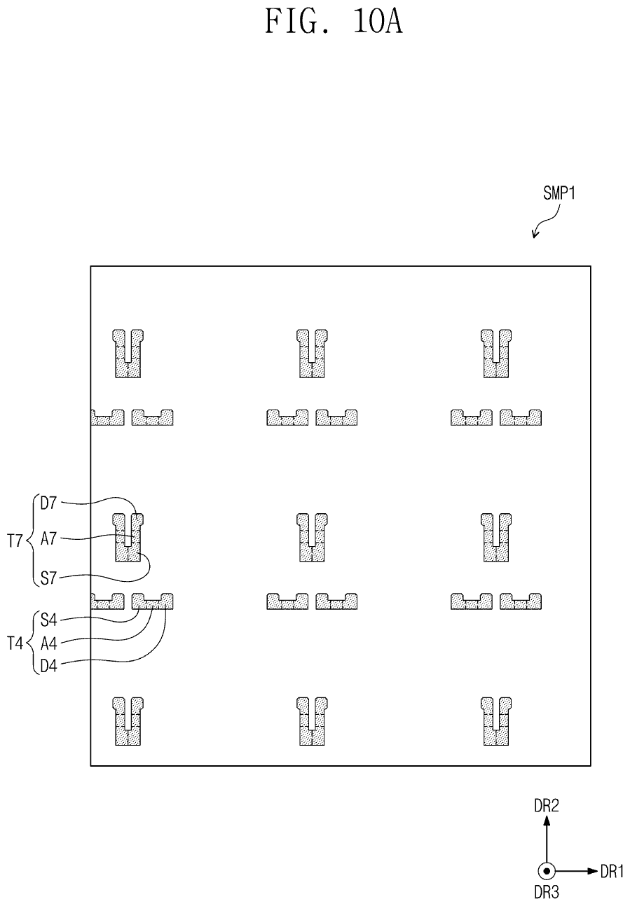

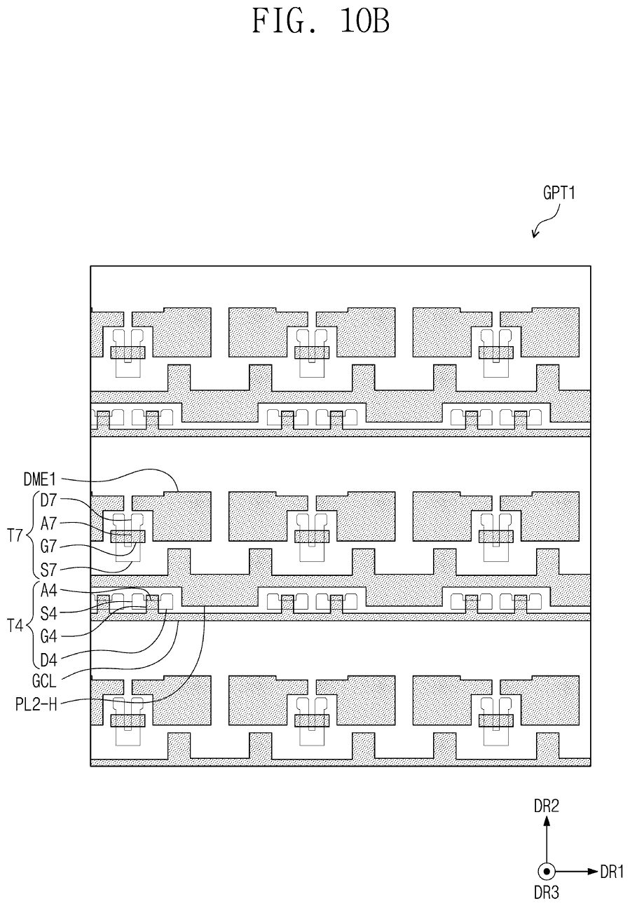

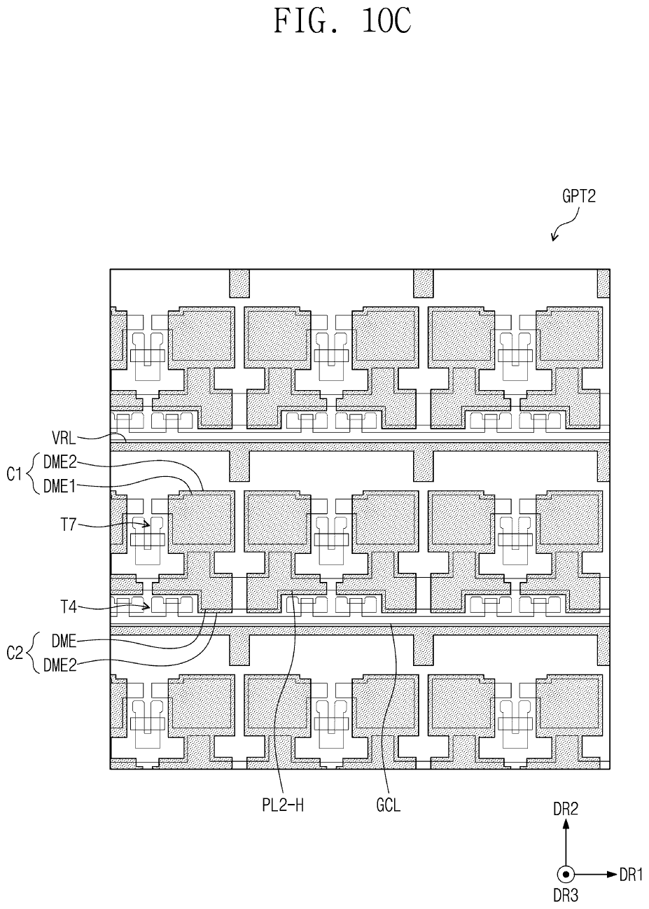

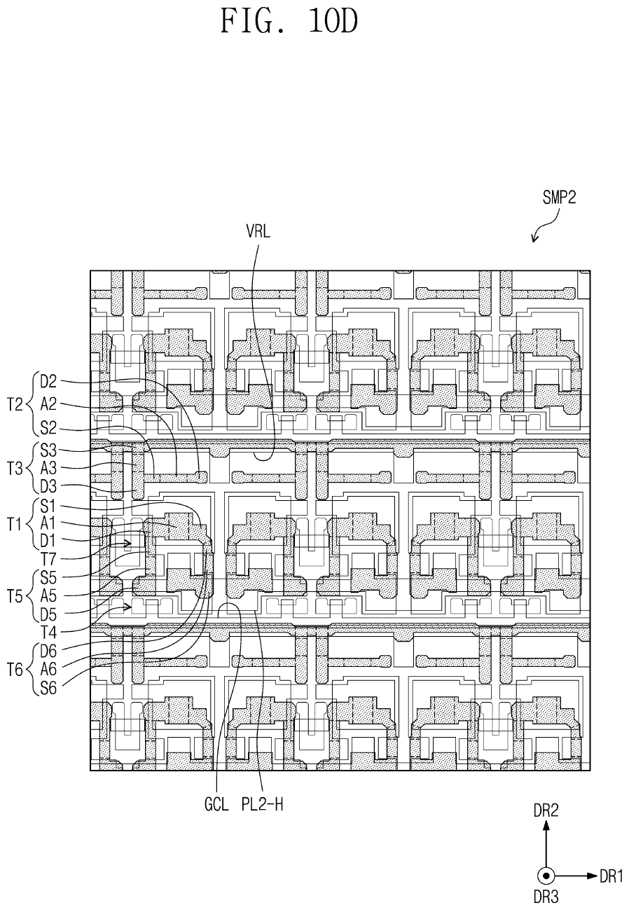

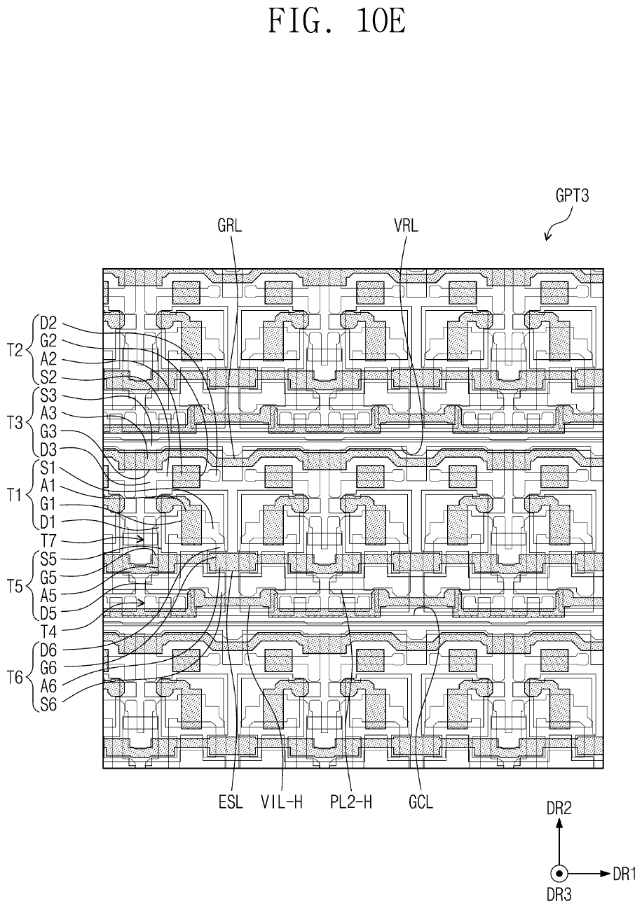

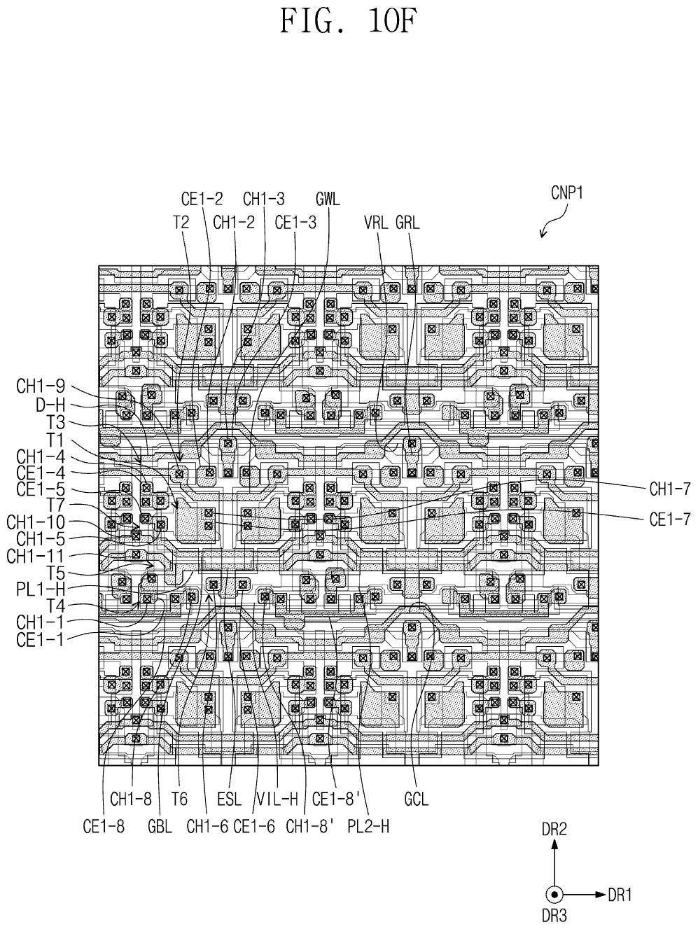

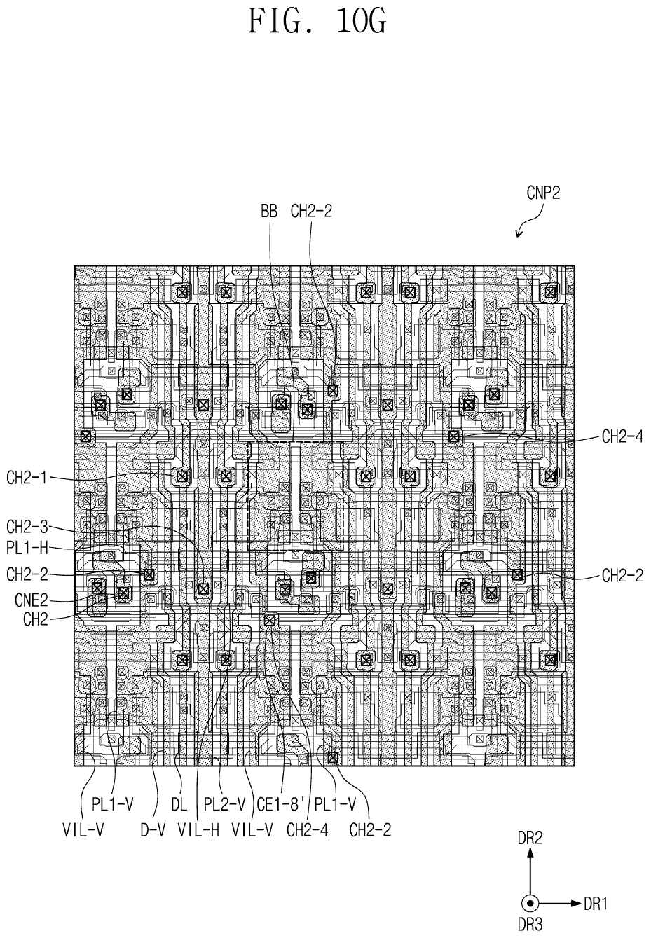

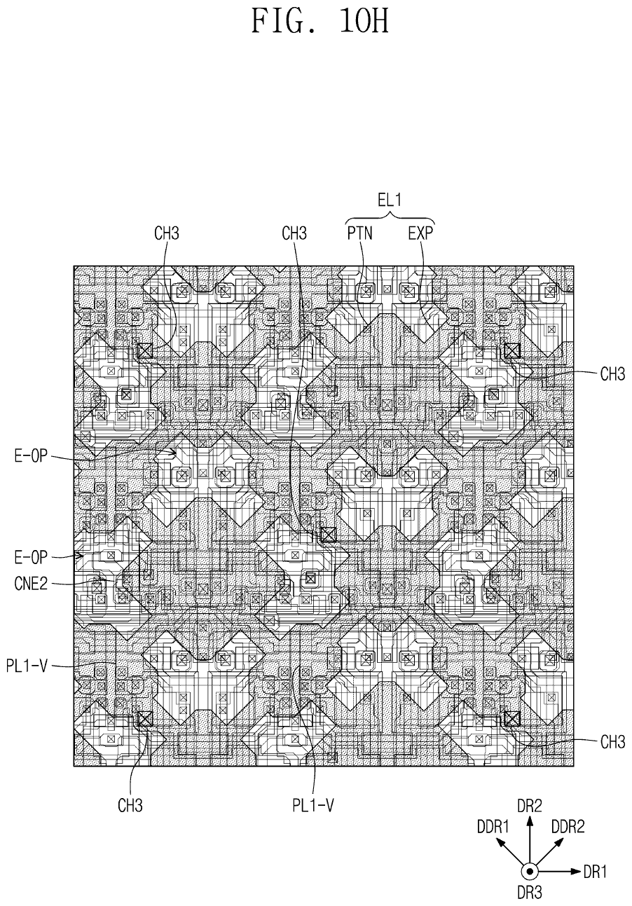

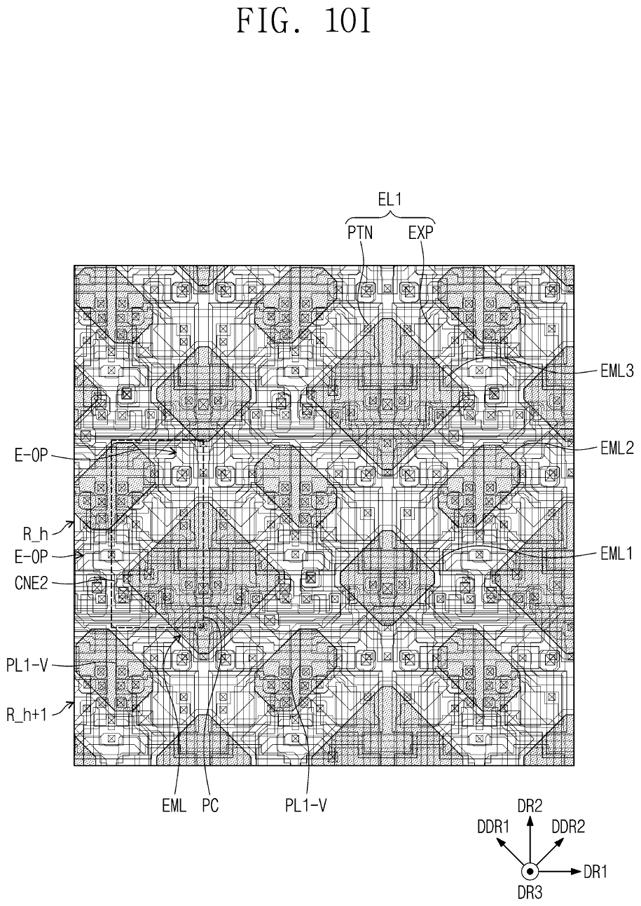

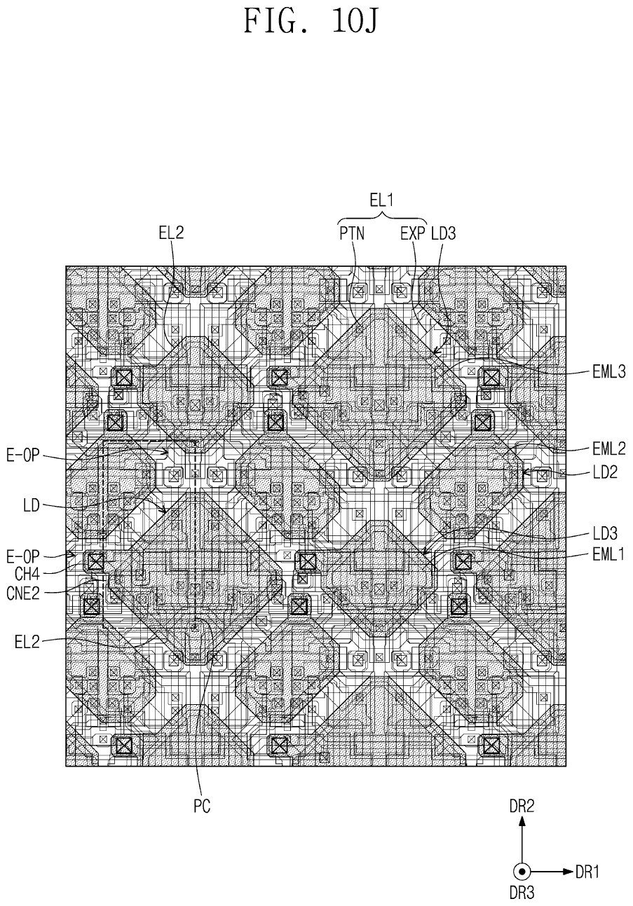

FIGS. 10A to 10J are views illustrating a planar structure of the pixel in FIG. 5 step by step (e.g., of each successive layer).

FIGS. 10A to 10J may be defined as layout drawings (e.g., of each layer). In FIGS. 10A to 10J, the configuration for the plurality of pixels PX is illustrated. However, each of the pixels PX have substantially the same configuration, and therefore only the configuration of the pixel PX disposed in the left central portion will be described below for economy of description.

Hereinafter, in FIGS. 10A to 10J, for convenience of description, the names and symbols “i-th” and “j-th” are omitted when lines are indicated. In the following description of FIGS. 10A to 10J, the term “overlap” represents a state in which components overlap each other when viewed from above the plane.

Referring to FIG. 10A, a first semiconductor pattern SMP1 may be disposed on the substrate SUB illustrated in FIG. 7. In an embodiment, the fourth source area S4, the fourth drain area D4, and the fourth channel area A4 of the fourth transistor T4 and the seventh source area S7, the seventh drain area D7, and the seventh channel area A7 of the seventh transistor T7 may be formed by the first semiconductor pattern SMP1.

The fourth channel area and A4 may be disposed between the fourth source area S4 and the fourth drain area D4, and the seventh channel area and A7 may be disposed between the seventh source area S7 and the seventh drain area D7.

Referring to FIGS. 10A and 10B, a first gate pattern GPT1 may be disposed on the first semiconductor pattern SMP1. In an embodiment, the first gate pattern GPT1 may include the seventh gate electrode G7, an initialization scan line GCL, a second horizontal power line PL2-H, and a first dummy electrode DME1.

The seventh gate electrode G7 of the seventh transistor T7 may be formed by the first gate pattern GPT1. The seventh gate electrode G7 may overlap the seventh channel area A7.

The initialization scan line GCL and the second horizontal power line PL2-H may extend in the first direction DR1 and may be adjacent to each other in the second direction DR2. The first dummy electrode DME1 may be adjacent to the seventh gate electrode G7.

The initialization scan line GCL may extend longitudinally (e.g., in the first direction DR1) to cross the first semiconductor pattern SMP1. In an embodiment, the fourth gate electrode G4 of the fourth transistor T4 may be formed by the initialization scan line GGL. A portion of the initialization scan line GCL that overlaps the first semiconductor pattern SMP1 when viewed from above the plane may be defined as the fourth gate electrode G4. The fourth gate electrode G4 may overlap the fourth channel area A4 when viewed from above the plane.

The second horizontal power line PL2-H may be disposed between the initialization scan line GCL and the first dummy electrode DME1 and between the initialization scan line GCL and the seventh gate electrode G7. In an embodiment, the above-described second power line PL2 may include the second horizontal power line PL2-H and a second vertical power line. The second vertical power line is illustrated in FIG. 10G.

In the following drawings, for convenience of description and simplification of reference numerals, the reference numerals of the source areas S4 and S7, the drain areas D4 and D7, the channel areas A4 and A7, and the gate electrodes G4 and G7 of the fourth transistor T4 and the seventh transistor T7 are omitted, and the reference numerals of the fourth transistor T4 and the seventh transistor T7 are illustrated.

In FIGS. 10C to 10J, the omitted reference numerals of the source areas S4 and S7, the drain areas D4 and D7, the channel areas A4 and A7, and the gate electrodes G4 and G7 refer to those in FIGS. 10A and 10B.

Referring to FIGS. 10A to 10C, a second gate pattern GPT2 may be disposed on the first gate pattern GPT1. In an embodiment, the second gate pattern GPT2 may include a second dummy electrode DME2 and the reference line VRL.

The second dummy electrode DME2 may overlap the first dummy electrode DME1 described above. In an embodiment, the first capacitor C1 illustrated in FIG. 5 may include the first dummy electrode DME1 and the second dummy electrode DME2.

A portion of the second horizontal power line PL2-H that overlaps the second dummy electrode DME2 may be defined as a dummy electrode DME. In an embodiment, the second capacitor C2 illustrated in FIG. 5 may include the dummy electrode DME and the second dummy electrode DME2.

The reference line VRL may extend longitudinally in the first direction DR1. The reference line VRL may be adjacent to the upper side of the second dummy electrode DME2.

In the following drawings, for convenience of description, the reference numerals of the first capacitor C1 and the second capacitor C2 are omitted, and in FIGS. 10D to 10J, the omitted reference numerals of the first capacitor C1 and the second capacitor C2 refer to those in FIG. 10C.

Referring to FIG. 10D, a second semiconductor pattern SMP2 may be disposed on the second gate pattern GPT2. In an embodiment, the first, second, third, fifth, and sixth source areas S1, S2, S3, S5, and S6, the first, second, third, fifth, and sixth drain areas D1, D2, D3, D5, and D6, and the first, second, third, fifth, and sixth channel areas A1, A2, A3, A5, and A6 of the first, second, third, fifth, and sixth transistors T1, T2, T3, T5, and T6 may be formed by the second semiconductor pattern SMP2.

The first, second, third, fifth, and sixth channel areas A1, A2, A3, A5, and A6 may be disposed between the first, second, third, fifth, and sixth source areas S1, S2, S3, S5, and S6 and the first, second, third, fifth, and sixth drain areas D1, D2, D3, D5, and D6.

In an embodiment, semiconductor patterns of the first transistor T1, the fifth transistor T5, and the sixth transistor T6 may be integrally formed with one another, and semiconductor patterns of the second transistor T2 and the third transistor T3 may be integrally formed with each other. The semiconductor patterns of the first transistor T1, the fifth transistor T5, and the sixth transistor T6 may be spaced apart from the semiconductor patterns of the second transistor T2 and the third transistor T3 in the second direction DR2. The semiconductor patterns of the first transistor T1 and the fifth transistor T5 may be adjacent to the fourth transistor T4 and the seventh transistor T7.

The fifth source area S5 of the fifth transistor T5 may extend from the first drain area D1 of the first transistor T1. The sixth drain area D6 of the sixth transistor T6 may extend from the first source area S1 of the first transistor T1. Depending on this structure, the fifth transistor T5 and the sixth transistor T6 may be connected to the first transistor T1.

The third drain area D3 of the third transistor T3 may extend from the second source area S2 of the second transistor T2. Depending on this structure, the third transistor T3 may be connected to the second transistor T2.

Referring to FIGS. 10A to 10E, a third gate pattern GPT3 may be disposed on the second semiconductor pattern SMP2. In an embodiment, the third gate pattern GPT3 may include the first gate electrode G1, the second gate electrode G2, a reset scan line GRL, a horizontal initialization line VIL-H, and an emission line ESL.

The first gate electrode G1 of the first transistor T1 and the second gate electrode G2 of the second transistor T2 may be formed by the third gate pattern GPT3. The first gate electrode G1 may overlap the first channel area A1 (e.g., in the third direction DR3), and the second gate electrode G2 may overlap the second channel area A2 (e.g., in the third direction DR3).

In an embodiment, the reset scan line GRL, the horizontal initialization line VIL-H, and the emission line ESL may extend longitudinally in the first direction DR1 and may be arranged in the second direction DR2. The emission line ESL may be disposed between the reset scan line GRL and the horizontal initialization line VIL-H.

The reset scan line GRL may be adjacent to the second transistor T2 and the third transistor T3. The reset scan line GRL may be adjacent to the reference line VRL. The horizontal initialization line VIL-H may be adjacent to the initialization scan line GCL. The horizontal initialization line VIL-H may be adjacent to the fourth transistor T4.

The reset scan line GRL may extend longitudinally (e.g., in the first direction DR1) to cross the second semiconductor pattern SMP2. The third gate electrode G3 of the third transistor T3 may be formed by the reset scan line GRL. A portion of the reset scan line GRL that overlaps the second semiconductor pattern SMP2 may be defined as the third gate electrode G3. The third gate electrode G3 may overlap the third channel area A3 (e.g., in the third direction DR3).

The emission line ESL may extend longitudinally to cross the second semiconductor pattern SMP2. In an embodiment, the fifth gate electrode G5 of the fifth transistor T5 and the sixth gate electrode G6 of the sixth transistor T6 may be formed by the emission line ESL. Portions of the emission line ESL that overlap the second semiconductor pattern SMP2 may be defined as the fifth gate electrode G5 and the sixth gate electrode G6. The fifth gate electrode G5 may overlap the fifth channel area A5 (e.g., in the third direction DR3), and the sixth gate electrode G6 may overlap the sixth channel area A6 (e.g., in the third direction DR3).

In the following drawings, for convenience of description and simplification of reference numerals, the reference numerals of the source areas S1, S2, S3, S5, and S6, the drain areas D1, D2, D3, D5, and D6, the channel areas A1, A2, A3, A5, and A6, and the gate electrodes G1, G2, G3, G5, and G6 of the first, second, third, fifth, and sixth transistors T1, T2, T3, T5, and T6 are omitted, and the reference numerals of the first, second, third, fifth, and sixth transistors T1, T2, T3, T5, and T6 are illustrated.

Hereinafter, in FIGS. 10F to 10J, the omitted reference numerals of the source areas S1, S2, S3, S5, and S6, the drain areas D1, D2, D3, D5, and D6, the channel areas A1, A2, A3, A5, and A6, and the gate electrodes G1, G2, G3, G5, and G6 refer to those in FIGS. 10D and 10E.

Referring to FIGS. 10A to 10F, a first connecting pattern CNP1 may be disposed on the second semiconductor pattern SMP2. In an embodiment, the first connecting pattern CNP1 may include a plurality of first connecting electrodes CE1-1 to CE1-8, a write scan line GWL, a compensation scan line GBL, a first horizontal power line PL1-H, and a horizontal dummy line D-H. The first connecting electrode CE1-1 may substantially correspond to the first connecting electrode CNE1 illustrated in FIG. 7.

In an embodiment, the write scan line GWL, the compensation scan line GBL, the first horizontal power line PL1-H, and the horizontal dummy line D-H may extend longitudinally in the first direction DE1 and may be arranged in the second direction DR2. The write scan line GWL may be adjacent to the second transistor T2. The compensation scan line GBL may be adjacent to the seventh transistor T7 and the first horizontal power line PL1-H. The first horizontal power line PL1-H may be adjacent to the seventh transistor T7. The horizontal dummy line D-H may be adjacent to the write scan line GWL.

In an embodiment, the write scan line GWL may be disposed between the horizontal dummy line D-H and the compensation scan line GBL. The compensation scan line GBL may be disposed between the write scan line GWL and the first horizontal power line PL1-H.

The first connecting electrodes CE1-1 to CE1-8, the write scan line GWL, the compensation scan line GBL, the first horizontal power line PL1-H, and the horizontal dummy line D-H may be disposed in the same layer as each other. For example, in an embodiment the first connecting electrodes CE1-1 to CE1-8, the write scan line GWL, the compensation scan line GBL, the first horizontal power line PL1-H, and the horizontal dummy line D-H may be disposed on (e.g., disposed directly thereon in the third direction DR3) the fifth insulating layer 50 illustrated in FIG. 7. In an embodiment, the first connecting electrodes CE1-1 to CE1-8, the write scan line GWL, the compensation scan line GBL, the first horizontal power line PL1-H, and the horizontal dummy line D-H may be simultaneously subjected to patterning with the same material.

The above-described first power line PL1 may include the first horizontal power line PL1-H and a first vertical power line electrically connected with each other. The first vertical power line is illustrated in FIG. 10G. The above-described initialization line VIL may include the horizontal initialization line VIL-H and a vertical initialization line electrically connected with each other. The vertical initialization line is illustrated in FIG. 10G.

A plurality of first contact holes CH1-1 to CH1-11 may be defined. The first contact holes CH1-1 may correspond to the first contact hole CH1 illustrated in FIG. 7. The first contact holes CH1-1 to CH1-11 may be defined in the first, second, third, fourth, or fifth insulating layer 10, 20, 30, 40, or 50 illustrated in FIG. 7.

In an embodiment, the first connecting electrode CE1-1 may be connected to the fourth source area S4 of the fourth transistor T4 and the fifth drain area D5 of the fifth transistor T5 through the first contact holes CH1-1 overlapping the first connecting electrode CE1-1 (e.g., in the third direction DR3). Accordingly, the fourth transistor T4 and the fifth transistor T5 may be connected with each other (e.g., electrically connected with each other) by the first-first connecting electrode CE1-1.

In an embodiment, the first connecting electrode CE1-2 may be connected to the second drain area D2 of the second transistor T2 through the first contact hole CH1-2 overlapping the first connecting electrode CE1-2.

In an embodiment, the first connecting electrode CE1-3 may be connected to the reference line VRL and the third source area S3 of the third transistor T3 through the first contact holes CH1-3 overlapping the first connecting electrode CE1-3 (e.g., in the third direction DR3). Accordingly, the third transistor T3 may be connected to (e.g., electrically connected thereto) the reference line VRL through the first connecting electrode CE1-3.

In an embodiment, the first connecting electrode CE1-4 may be connected to the first dummy electrode DME1, the first gate electrode G1 of the first transistor T1, and the third drain area D3 of the third transistor T3 through the first contact holes CH1-4 overlapping the first connecting electrode CE1-4 (e.g., in the third direction DR3). Accordingly, the first dummy electrode DME, the first transistor T1, and the third transistor T3 may be connected with one another (e.g., electrically connected thereto) by the first connecting electrode CE1-4.

In an embodiment, the first connecting electrode CE1-5 may be connected to the first drain area D1 of the first transistor T1 and the seventh drain area D7 of the seventh transistor T7 through the first contact holes CH1-5 overlapping the first connecting electrode CE1-5. Accordingly, the first transistor T1 and the seventh transistor T7 may be connected with each other (e.g., electrically connected thereto) by the first connecting electrode CE1-5.

In an embodiment, the first connecting electrode CE1-6 may be connected to the sixth source area S6 of the sixth transistor T6 through the first contact hole CH1-6 overlapping the first connecting electrode CE1-6.

In an embodiment, the first connecting electrode CE1-7 may be connected to the second dummy electrode DME2 and the first source area S1 of the first transistor T1 through the first contact hole CH1-7 overlapping the first connecting electrode CE1-7. Accordingly, the second dummy electrode DME2 and the first transistor T1 may be connected with each other (e.g. electrically connected thereto) by the first connecting electrode CE1-7.

In an embodiment, the first connecting electrode CE1-8 may be connected to the horizontal initialization line VIL-H and the fourth drain area D4 of the fourth transistor T4 through the first contact holes CH1-8 overlapping the first connecting electrode CE1-8 (e.g., in the third direction DR3). Accordingly, the fourth transistor T4 may be connected to (e.g., electrically connected thereto) the horizontal initialization line VIL-H through the first connecting electrode CE1-8. In an embodiment, a first connecting electrode CE1-8′ having a shape similar to the shape of the first connecting electrode CE1-8 may be connected to the horizontal initialization line VIL-H through a first contact hole CH1-8′.

In an embodiment, the write scan line GWL may be connected to the second drain area D2 of the second transistor T2 through the first contact hole CH1-9 overlapping the write scan line GWL (e.g., in the third direction DR3). The compensation scan line GBL may be connected to the seventh gate electrode G7 of the seventh transistor T7 through the first contact hole CH1-10 overlapping the compensation scan line GBL. The first horizontal power line PL1-H may be connected to the seventh source area S7 of the seventh transistor T7 through the first contact hole CH1-11 overlapping the first horizontal power line PL1-H.

In the following drawings, for convenience of description, the reference numerals of the first connecting electrodes CE1-1 to CE1-8 and the first contact holes CH1-1 to CH1-11 are omitted, and the omitted reference numerals of the first connecting electrodes CE1-1 to CE1-8 and the first contact holes CH1-1 to CH1-11 in FIGS. 10G to 10J refer to those in FIG. 10F.

In addition, in the following drawings, the reference numerals of the write scan line GWL, the initialization scan line GCL, the compensation scan line GBL, the reset scan line GRL, the reference line VRL, the emission line ESL, and the horizontal dummy line D-H are omitted, and the omitted reference numerals of the write scan line GWL, the initialization scan line GCL, the compensation scan line GBL, the reset scan line GRL, the reference line VRL, the emission line ESL, and the horizontal dummy line D-H in FIGS. 10G to 10J refer to those in FIG. 10F.

Referring to FIGS. 10A to 10G, a second connecting pattern CNP2 may be disposed on the first connecting pattern CNP1. In an embodiment, the second connecting pattern CNP2 may include the second connecting electrode CNE2, the first vertical power line PL1-V, the second vertical power line PL2-V, the vertical initialization line VIL-V, a data line DL, and a vertical dummy line D-V. The second connecting electrode CNE2 may be the second connecting electrode CEN2 illustrated in FIG. 7.

In an embodiment, the above-described first power line PL1 may include the first vertical power line PL1-V and the first horizontal power line PL1-H. The above-described second power line PL2 may include the second vertical power line PL2-V and the second horizontal power line PL2-H. The above-described initialization line VIL may include the vertical initialization line VIL-V and the horizontal initialization line VIL-H.

The first vertical power line PL1-V and the first horizontal power line PL1-H may be disposed in different layers from each other. For example, in an embodiment the first vertical power line PL1-V may be disposed above the first horizontal power line PL1-H.

The second vertical power line PL2-V and the second horizontal power line PL2-H may be disposed in different layers from each other. In an embodiment, the second vertical power line PL2-V may be disposed above the second horizontal power line PL2-H (e.g., in the third direction DR3).

The vertical initialization line VIL-V and the horizontal initialization line VIL-H may be disposed in different layers from each other. In an embodiment, the vertical initialization line VIL-V may be disposed above the horizontal initialization line VIL-H (e.g., in the third direction DR3).

In an embodiment, the first vertical power line PL1-V, the second vertical power line PL2-V, the vertical initialization line VIL-V, the data line DL, and the vertical dummy line D-V may extend longitudinally in the second direction DR2 and may be arranged in the first direction DR1.

The first vertical power line PL1-V may be disposed between the vertical initialization line VIL-V and the vertical dummy line D-V (e.g., in the first direction DR1). The vertical dummy line D-V may be disposed between the first vertical power line PL1-V and the data line DL (e.g., in the first direction DR1). The data line DL may be disposed between the vertical dummy line D-V and the second vertical power line PL2-V (e.g., in the first direction DR1).

In an embodiment, among a plurality of first vertical power lines PL1-V and a plurality of vertical initialization lines VIL-V, the k-th first vertical power line PL1-V and the k-th vertical initialization line VIL-V may be adjacent to each other in the first direction DR1. “k” is a natural number.

In an embodiment, the second connecting electrode CNE2, the first vertical power line PL1-V, the second vertical power line PL2-V, the vertical initialization line VIL-V, the data line DL, and the vertical dummy line D-V may be disposed in the same layer as each other. For example, the second connecting electrode CNE2, the first vertical power line PL1-V, the second vertical power line PL2-V, the vertical initialization line VIL-V, the data line DL, and the vertical dummy line D-V may be disposed on the sixth insulating layer 60 illustrated in FIG. 7 (e.g., disposed directly thereon in the third direction DR3).

In an embodiment, the second connecting electrode CNE2, the first vertical power line PL1-V, the second vertical power line PL2-V, the vertical initialization line VIL-V, the data line DL, and the vertical dummy line D-V may be simultaneously subjected to pattering with the same material.

A plurality of second contact holes CH2 and CH2-1 to CH2-4 may be defined. The second contact hole CH2 may be the second contact hole CH2 illustrated in FIG. 7. The second contact holes CH2 and CH2-1 to CH2-4 may be defined in the sixth insulating layer 60 illustrated in FIG. 7.

In an embodiment, the second connecting electrode CNE2 may be connected to the first connecting electrode CE1-1 through the second contact hole CH2 overlapping the second connecting electrode CNE2 (e.g., in the third direction DR3). Accordingly, the second connecting electrode CNE2 may be connected to (e.g., electrically connected thereto) the fifth transistor T5 through the first connecting electrode CE1-1.

In an embodiment, the data line DL may be connected to the first connecting electrode CE1-2 through the second contact hole CH2-1 overlapping the data line DL (e.g., in the third direction DR3). Accordingly, the data line DL may be connected to (e.g., electrically connected thereto) the second transistor T2 through the first connecting electrode CE1-2.

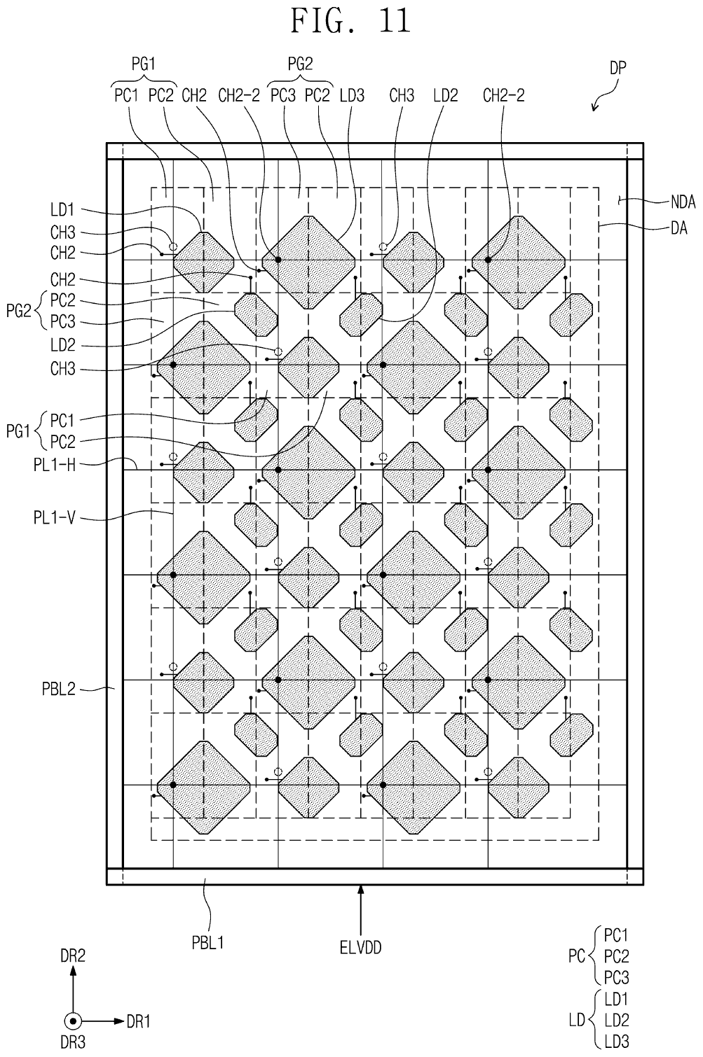

In an embodiment, the first vertical power line PL1-V may be connected to the first horizontal power line PL1-H through the second contact hole CH2-2 overlapping the first vertical power line PL1-V. The plurality of first vertical power lines PL1-V may be electrically connected with a plurality of first horizontal power lines PL1-H through the second contact holes CH2-2 illustrated in FIG. 10G. The first vertical power lines PL1-V, the first horizontal power lines PL1-H, and the second contact holes CH2-2 will be briefly illustrated in FIG. 11.

In an embodiment, the second vertical power line PL2-V may be connected to the first connecting electrode CE1-6 through the second contact hole CH2-3 overlapping the second vertical power line PL2-V (e.g., in the third direction DR3). Accordingly, the second vertical power line PL2-V may be connected to (e.g., electrically connected thereto) the sixth transistor T6 through the first connecting electrode CE1-6.

In an embodiment, the vertical initialization line VIL-V may be connected to the first connecting electrode CE1-8′ through the second contact hole CH2-4 overlapping the vertical initialization line VIL-V (e.g., in the third direction DR3). Accordingly, the vertical initialization line VIL-V may be electrically connected to the horizontal initialization line VIL-H through the first connecting electrode CE1-8′.

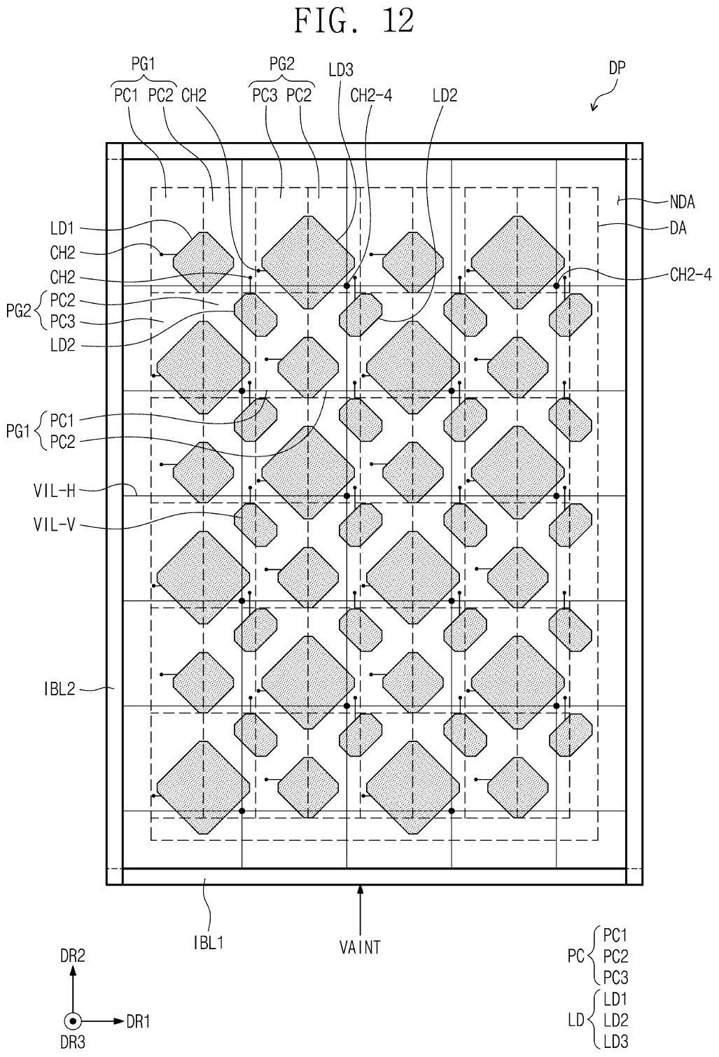

In an embodiment, the plurality of vertical initialization lines VIL-V may be electrically connected with a plurality of horizontal initialization lines VIL-H through the second contact holes CH2-4 illustrated in FIG. 10G. The vertical initialization lines VIL-V, the horizontal initialization lines VIL-H, and the second contact holes CH2-4 will be briefly illustrated in FIG. 12.

In an embodiment, as in an area BB illustrated in FIG. 10G, a portion of the first vertical power line PL1-V and a portion of the vertical initialization line VIL-V adjacent to each other in the first direction DR1 may have shapes symmetrical to each other in the first direction DR1.

Hereinafter, in FIGS. 10H to 10J, for convenience of description, the remaining reference numerals other than the reference numerals of the first vertical power line PL1-V and the second connecting electrode CNE2 among the reference numerals illustrated in FIG. 10G are all omitted, and the omitted reference numerals in FIGS. 10H to 10J refer to those in FIG. 10G.

Referring to FIGS. 10A to 10H, the first electrode EL1 may be disposed on the second connecting pattern CNP2. The first electrode EL1 may be the first electrode EL1 illustrated in FIG. 7. A plurality of openings E-OP may be defined in the first electrode EL1. The openings E-OP may correspond to the second opening OP2 illustrated in FIG. 7.

In an embodiment, the first electrode EL1 may include a plurality of first electrode patterns PTN arranged in a first diagonal direction DDR1 and a second diagonal direction DDR2 and extending patterns EXP extending from the first electrode patterns PTN in the first diagonal direction DDR1 and the second diagonal direction DDR2. In an embodiment, the first electrode pattern PTN and the extending patterns EXP may be integrally formed with each other. For example, the first electrodes EL1 (e.g., the anodes) of the pixels PX may be integrally formed. The openings E-OP may be defined between the first electrode patterns PTN and the extending patterns EXP.

The first diagonal direction DDR1 may be defined as a direction that crosses the first direction DR1 and the second direction DR2 on the plane defined by the first direction DR1 and the second direction DR2. The second diagonal direction DDR2 may be defined as a direction that crosses the first diagonal direction DDR1 on the plane defined by the first direction DR1 and the second direction DR2. For example, in an embodiment the first direction DR1 and the second direction DR2 may cross each other at a substantially right angle, and the first diagonal direction DDR1 and the second diagonal direction DDR2 may cross each other at a substantially right angle. However, embodiments of the present disclosure are not necessarily limited thereto.

The third contact holes CH3 may be defined. The third contact holes CH3 may be defined in the seventh insulating layer 70 illustrated in FIG. 7. In an embodiment, the first electrode EL1 may be connected to the first vertical power lines PL1-V through the third contact holes CH3 overlapping the first electrode EL1 (e.g., in the third direction DR3). Accordingly, the first electrode EL1 may be connected to the first power line PL1.

The third contact holes CH3 may not overlap (e.g., in the third direction DR3) the second contact holes CH2-2 illustrated in FIG. 10G. The third contact holes CH3 will be simplified in FIG. 11. Hereinafter, in FIGS. 10I and 10J, the reference numerals of the third contact holes CH3 are omitted.

Referring to FIGS. 10A to 10I, a plurality of emissive layers EML may be disposed on the first electrode EL1. The emissive layers EML may correspond to the emissive layer EML illustrated in FIG. 7. The emissive layers EML may be disposed on the first electrode patterns PTN, respectively. The emissive layers EML may overlap the first electrode patterns PTN, respectively (e.g., in the third direction DR3). The emissive layers EML, when viewed from above the plane, may have a smaller area than the first electrode patterns PTN. In an embodiment, the emissive layers EML may have an approximately rhombus shape.

In an embodiment, the emissive layers EML may include a plurality of first emissive layers EML1 that emit red light, a plurality of second emissive layers EML2 that emit green light, and a plurality of third emissive layers EML3 that emit blue light. However, embodiments of the present disclosure are not necessarily limited thereto.

The emissive layers EML may be arranged in the first diagonal direction DDR1 and the second diagonal direction DDR2. When the second diagonal direction DDR2 is defined as a row, the first emissive layers EML1 and the second emissive layers EML2 may be alternately disposed in the second diagonal direction DDR2 in the h-th row R_h. In an embodiment, the second emissive layers EML2 and the third emissive layers EML3 may be alternately disposed in the second diagonal direction DDR2 in the (h+1)th row R_h+1.

The area where the first to seventh transistors T1 to T7, the first capacitor C1, and the second capacitor C2 described above are disposed is illustrated by a dotted rectangular line in FIG. 10I. The area illustrated by the dotted rectangular line may be defined as the pixel circuit PC. For example, the pixel circuit PC may include the first to seventh transistors T1 to T7, the first capacitor C1, and the second capacitor C2.

Referring to FIGS. 10A to 10J, a plurality of second electrodes EL2 may be disposed on the emissive layers EML, respectively. The second electrodes EL2 may protrude towards the openings E-OP and may be connected to (e.g., directly connected thereto) the second connecting electrodes CNE2, respectively, through contact holes CH4 overlapping the openings E-OP. The contact holes CH4 may substantially correspond to the first opening OP1 illustrated in FIG. 7.

In an embodiment, each of light emitting elements LD may include the first electrode pattern PTN, the emissive layer EML, and the second electrode EL2 described above. Each of the light emitting elements LD may correspond to the light emitting element LD illustrated in FIG. 7. Each of the light emitting elements LD may be connected to a corresponding pixel circuit PC through a corresponding second connecting electrode CNE2.

In an embodiment, the light emitting elements LD may include a plurality of first light emitting elements LD1, a plurality of second light emitting elements LD2, and a plurality of third light emitting elements LD3. In an embodiment, each of the first light emitting elements LD1 may include the first emissive layer EML1 and may be defined as a red light emitting element. Each of the second light emitting elements LD2 may include the second emissive layer EML2 and may be defined as a green light emitting element. Each of the third light emitting elements LD3 may include the third emissive layer EML3 and may be defined as a blue light emitting element.

FIG. 11 is a plan view of the display panel schematically illustrating a first power line, light emitting elements, and pixel circuits according to an embodiment of the present disclosure.

Referring to FIGS. 10G to 10J and 11, the display area DA may include the plurality of pixel circuits PC. The boundaries between the pixel circuits PC and the periphery of the display area DA are illustrated by dotted lines in FIG. 11.

The light emitting elements LD may be connected to the pixel circuits PC, respectively. In FIG. 11, the second contact holes CH2 are illustrated as connection points between the light emitting elements LD and the pixel circuits PC. In FIG. 11, the second contact holes CH2 are illustrated as circular dots having a black color.

In an embodiment, the pixel circuits PC may include a plurality of first pixel circuits PC1, a plurality of second pixel circuits PC2, and a plurality of third pixel circuits PC3. The first pixel circuits PC1 may be connected to the first light emitting elements LD1, respectively. The second pixel circuits PC2 may be connected to the second light emitting elements LD2, respectively. The third pixel circuits PC3 may be connected to the third light emitting elements LD3, respectively.

The pixel circuits PC may be grouped into a plurality of first pixel circuit groups PG1 and a plurality of second pixel circuit groups PG2. The first pixel circuit groups PG1 and the second pixel circuit groups PG2 may be alternately disposed in the first direction DR1 and the second direction DR2.

In an embodiment, each of the first pixel circuit groups PG1 may include the first pixel circuit PC1 and the second pixel circuit PC2 disposed in (e.g., arranged in) the first direction DR1. Each of the second pixel circuit groups PG2 may include the third pixel circuit PC3 and the second pixel circuit PC2 disposed in (e.g., arranged in) the first direction DR1.

In an embodiment, the first power line PL1 may include a plurality of first horizontal power lines PL1-H that extend longitudinally in the first direction DR1 and that are arranged in the second direction DR2 and a plurality of first vertical power lines PL1-V that extend longitudinally in the second direction DR2 and that are arranged in the first direction DR1. The first horizontal power lines PL1-H and the first vertical power lines PL1-V may extend to cross one another when viewed from above the plane.

In an embodiment, the first horizontal power lines PL1-H and the first vertical power lines PL1-V may be connected to each other through the second contact holes CH2-2. The first horizontal power lines PL1-H and the first vertical power lines PL1-V may be connected with one another through the second contact holes CH2-2 at some of the intersections of the first horizontal power lines PL1-H and the first vertical power lines PL1-V.

The second contact holes CH2-2 may be defined as connection points between the first horizontal power lines PL1-H and the first vertical power lines PL1-V. In an embodiment, the connection points between the first horizontal power lines PL1-H and the first vertical power lines PL1-V may overlap the second pixel circuit groups PG2. For example, the connection points between the first horizontal power lines PL1-H and the first vertical power lines PL1-V may overlap the third light emitting elements LD3.

In an embodiment, the first horizontal power lines PL1-H may be alternately connected to two first vertical power lines PL1-V adjacent to each other. In addition, the first vertical power lines PL1-V may be alternately connected to two first horizontal power lines PL1-H adjacent to each other. For example, in an embodiment the first horizontal power lines PL1-H may be continuously arranged so that each is connected to one of the first vertical power lines PL1-V and is not connected to the adjacent one of the first vertical power lines PL1-V in an alternating manner. The first vertical power lines PL1-V may be continuously arranged so that each is connected to one of the first horizontal power lines PL1-H and is not connected to the adjacent one of first horizontal power lines PL1-H in an alternating manner.

In an embodiment as shown in FIG. 11, the odd-numbered first horizontal power lines PL1-H may be connected to the even-numbered first vertical power lines PL1-V. In addition, the even-numbered first horizontal power lines PL1-H may be connected to the odd-numbered first vertical power lines PL1-V. The odd-numbered first horizontal power lines PL1-H may not be connected to the odd-numbered first vertical power lines PL1-V. The even-numbered first horizontal power lines PL1-H may not be connected to the even-numbered first vertical power lines PL1-V. However, embodiments of the present disclosure are not necessarily limited thereto.

The display panel DP may include a plurality of first power bus lines PBL1 and a plurality of second power bus lines PBL2 disposed in the non-display area NDA. In an embodiment, the first power bus lines PBL1 may extend longitudinally in the first direction DR1 and may be disposed in the non-display areas NDA adjacent to the opposite sides of the display area DA that face away from each other in the second direction DR2. The second power bus lines PBL2 may extend longitudinally in the second direction DR2 and may be disposed in the non-display areas NDA adjacent to the opposite sides of the display area DA that face away from each other in the first direction DR1.

In an embodiment, the first power bus lines PBL1 and the second power bus lines PBL2 may be disposed to surround the display area DA (e.g., completely surround in a plan view). The first vertical power lines PL1-V may be connected to (e.g., directly connected thereto) the first power bus lines PBL1. The first horizontal power lines PL1-H may be connected to (e.g., directly connected thereto) the second power bus lines PBL2. The first power bus line PBL1 adjacent to the lower side of the display area DA may receive the first power supply voltage ELVDD.

In an embodiment, the first power bus lines PBL1 may be disposed in the same layer as the first connecting electrode CNE1 or the second connecting electrode CNE2 illustrated in FIG. 7. The second power bus lines PBL2 may be disposed in the same layer as the first connecting electrode CNE1 or the second connecting electrode CNE2 illustrated in FIG. 7.

The first power bus lines PBL1 and the second power bus lines PBL2 may be disposed in different layers from each other. For example, in an embodiment the first power bus lines PBL1 may be disposed in the same layer as the second connecting electrode CNE2, and the second power bus lines PBL2 may be disposed in the same layer as the first connecting electrode CNE1. In this embodiment, the first power bus lines PBL1 and the second power bus lines PBL2 may be connected through contact holes that are defined in an insulating layer (e.g., the sixth insulating layer 60 illustrated in FIG. 7) between the first power bus lines PBL1 and the second power bus lines PBL2.

However, embodiments of the present disclosure are not necessarily limited thereto and the first power bus lines PBL1 and the second power bus lines PBL2 may be disposed in the same layer as each other in an embodiment. In this embodiment, the first power bus lines PBL1 and the second power bus lines PBL2 may be integrally formed with each other.

As illustrated in FIG. 10H, the first electrode EL1 may be connected to the first vertical power lines PL1-V through the third contact holes CH3. In FIG. 11, the third contact holes CH3 are illustrated by circular dotted lines. The third contact holes CH3 may be defined as connection points between the first electrode EL1 and the first vertical power lines PL1-V.

In an embodiment, the connection points between the first electrode EL1 and the first vertical power lines PL1-V may be adjacent to the intersections of the odd-numbered first horizontal power lines PL1-H and the odd-numbered first vertical power lines PL1-V.

In an embodiment of the present disclosure, the first power line PL1 may include the first vertical power lines PL1-V and the first horizontal power lines PL1-H that cross one another to form a mesh shape and that are electrically connected with one another. Accordingly, the area by which the first power line PL1 is disposed may be increased so that the line resistance of the first power line PL1 may be decreased. Thus, the first power supply voltage ELVDD may be more stably applied to the pixels PX.

In some embodiments, additional dummy power lines may be included. For example, in an embodiment dummy power lines may be disposed on the seventh insulating layer 70 illustrated in FIG. 7, an additional insulating layer may be disposed on the dummy power lines, and the pixel defining layer PDL may be disposed on the additional insulating layer. In an embodiment, the dummy power lines may be connected to the first vertical power lines PL1-V through contact holes defined in the additional insulating layer.

FIG. 12 is a plan view of the display panel schematically illustrating initialization lines, light emitting elements, and pixel circuits according to an embodiment of the present disclosure.

The structure of the light emitting elements LD and the pixel circuits PC illustrated in FIG. 12 is the same as the structure illustrated in FIG. 11, and therefore the configuration for the initialization line VIL will be mainly described below.

Referring to FIG. 12, the initialization line VIL may include a plurality of horizontal initialization lines VIL-H that extend longitudinally in the first direction DR1 and that are arranged in the second direction DR2 and a plurality of vertical initialization lines VIL-V that extend longitudinally in the second direction DR2 and that are arranged in the first direction DR1. The horizontal initialization lines VIL-H and the vertical initialization lines VIL-V may extend to cross one another when viewed from above the plane.

In an embodiment, the horizontal initialization lines VIL-H and the vertical initialization lines VIL-V may be connected through the second contact holes CH2-4. The second contact holes CH2-4 may be defined as connection points between the horizontal initialization lines VIL-H and the vertical initialization lines VIL-V. The connection points between the horizontal initialization lines VIL-H and the vertical initialization lines VIL-V may overlap the second pixel circuit groups PG2. For example, in an embodiment the connection points between the horizontal initialization lines VIL-H and the vertical initialization lines VIL-V may be adjacent to the third light emitting elements LD3.

In an embodiment, the horizontal initialization lines VIL-H may be alternately connected to two vertical initialization lines VIL-V adjacent to each other. In addition, the vertical initialization lines VIL-V may be alternately connected to two horizontal initialization lines VIL-H adjacent to each other. For example, in an embodiment the first horizontal initialization lines VIL-H may be continuously arranged so that each is connected to one of the first vertical initialization lines VIL-V and is not connected to the adjacent one of the first vertical initialization lines VIL-V in an alternating manner. The first vertical initialization lines VIL-V may be continuously arranged so that each is connected to one of the first horizontal initialization lines VIL-H and is not connected to the adjacent one of the first horizontal initialization lines VIL-H in an alternating manner.

In an embodiment as shown in FIG. 12, the odd-numbered horizontal initialization lines VIL-H may be connected to the even-numbered vertical initialization lines VIL-V. In addition, the even-numbered horizontal initialization lines VIL-H may be connected to the odd-numbered vertical initialization lines VIL-V. The odd-numbered horizontal initialization lines VIL-H may not be connected to the odd-numbered vertical initialization lines VIL-V. The even-numbered horizontal initialization lines VIL-H may not be connected to the even-numbered vertical initialization lines VIL-V. However, embodiments of the present disclosure are not necessarily limited thereto.

The display panel DP may include a plurality of first initialization bus lines IBL1 and a plurality of second initialization bus lines IBL2 disposed in the non-display area NDA. In an embodiment, the first initialization bus lines IBL1 may extend longitudinally in the first direction DR1 and may be disposed in the non-display areas NDA adjacent to the opposite sides of the display area DA that face away from each other in the second direction DR2. The second initialization bus lines IBL2 may extend longitudinally in the second direction DR2 and may be disposed in the non-display areas NDA adjacent to the opposite sides of the display area DA that face away from each other in the first direction DR1.

In an embodiment, the first initialization bus lines IBL1 and the second initialization bus lines IBL2 may be disposed to surround the display area DA (e.g., completely surround in a plan view). The vertical initialization lines VIL-V may be connected to (e.g., directly connected thereto) the first initialization bus lines IBL1. The horizontal initialization lines VIL-H may be connected to (e.g., directly connected thereto) the second initialization bus lines IBL2. The first initialization bus line IBL1 adjacent to the lower side of the display area DA may receive the initialization voltage VAINT.

In an embodiment, the first initialization bus lines IBL1 may be disposed in the same layer as the first connecting electrode CNE1 or the second connecting electrode CNE2 illustrated in FIG. 7. The second initialization bus lines IBL2 may be disposed in the same layer as the first connecting electrode CNE1 or the second connecting electrode CNE2 illustrated in FIG. 7.

In an embodiment, the first initialization bus lines IBL1 and the second initialization bus lines IBL2 may be disposed in different layers from each other. For example, in an embodiment the first initialization bus lines IBL1 may be disposed in the same layer as the first connecting electrode CNE1, and the second initialization bus lines IBL2 may be disposed in the same layer as the second connecting electrode CNE2. In this embodiment, the first initialization bus lines IBL1 and the second initialization bus lines IBL2 may be connected through contact holes that are defined in an insulating layer (e.g., the sixth insulating layer 60 illustrated in FIG. 7) between the first initialization bus lines IBL1 and the second initialization bus lines IBL2.

However, embodiments of the present disclosure are not necessarily limited thereto. For example, in an embodiment the first initialization bus lines IBL1 and the second initialization bus lines IBL2 may be disposed in the same layer as each other. In this embodiment, the first initialization bus lines IBL1 and the second initialization bus lines IBL2 may be integrally formed with each other.

In an embodiment, the first initialization bus lines IBL1 and the second initialization bus lines IBL2 may be disposed outward of the first power bus lines PBL1 and the second power bus lines PBL2.

In an embodiment of the present disclosure, the initialization line VIL may include the vertical initialization lines VIL-V and the horizontal initialization lines VIL-H that cross one another to form a mesh shape and that are electrically connected with one another. Accordingly, the area by which the initialization line VIL is disposed may be increased so that the line resistance of the initialization line VIL may be decreased. Thus, the initialization voltage VAINT may be more stably applied to the pixels PX.

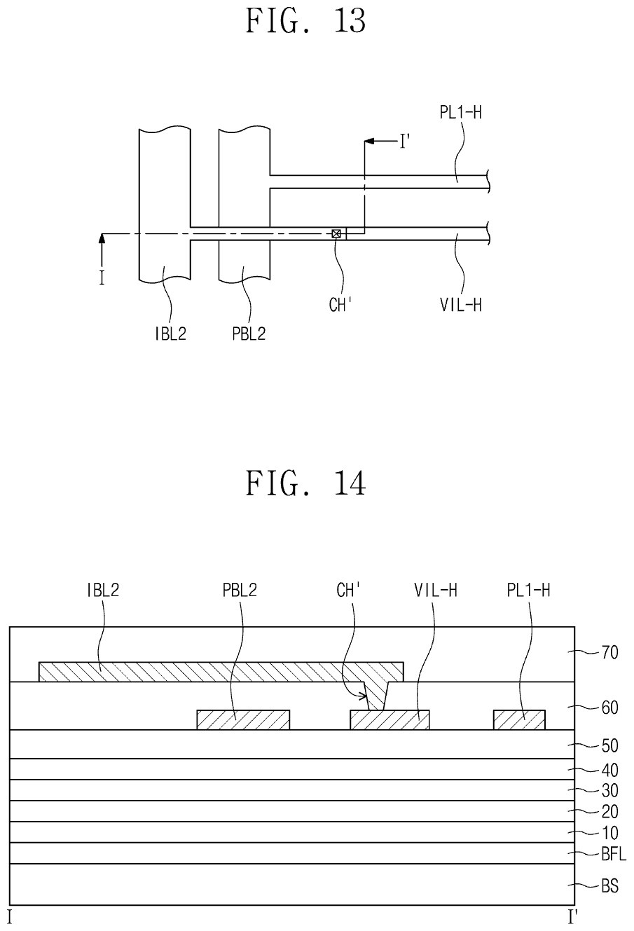

FIG. 13 is an enlarged view of the first horizontal power line connected to the second power bus line and the horizontal initialization line connected to the second initialization bus line in FIGS. 11 and 12. FIG. 14 is a cross-sectional view taken along line I-I′ illustrated in FIG. 13.

Referring to FIGS. 13 and 14, the second initialization bus line IBL2 may be disposed outward of the second power bus line PBL2 (e.g., in a plan view). In an embodiment, the second power bus line PBL2, the first horizontal power line PL1-H, and the horizontal initialization line VIL-H may be disposed on the fifth insulating layer 50, and the second initialization bus line IBL2 may be disposed on the sixth insulating layer 60. In FIG. 14, the second initialization bus line IBL2 is illustrated as a single layer without being illustrated as the first to third layers L1 to L3 like the second connecting electrode CNE2 illustrated in FIG. 7 for economy of explanation.

In an embodiment, the first horizontal power lines PL1-H may be integrally formed with the second power bus lines PBL2. The horizontal initialization line VIL-H may be connected to (e.g., directly connected thereto) the second initialization bus line IBL2 through a contact hole CH′ defined in the sixth insulating layer 60. Accordingly, the horizontal initialization line VIL-H may be insulated from the second power bus line PBL2 and may be connected to the second initialization bus line IBL2. In an embodiment, in a similar configuration, the vertical initialization line VIL-V may also be insulated from the first power bus line PBL1 and may be connected to the first initialization bus line IBL1.

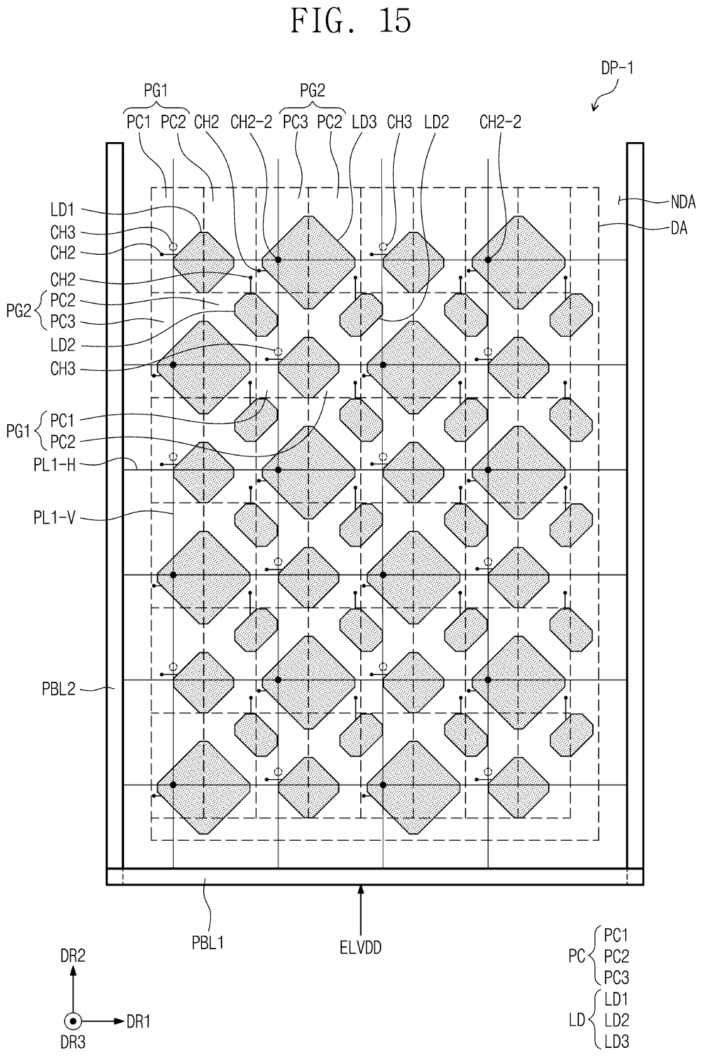

FIGS. 15 to 20 are views illustrating configurations of display panels according to embodiments of the present disclosure.

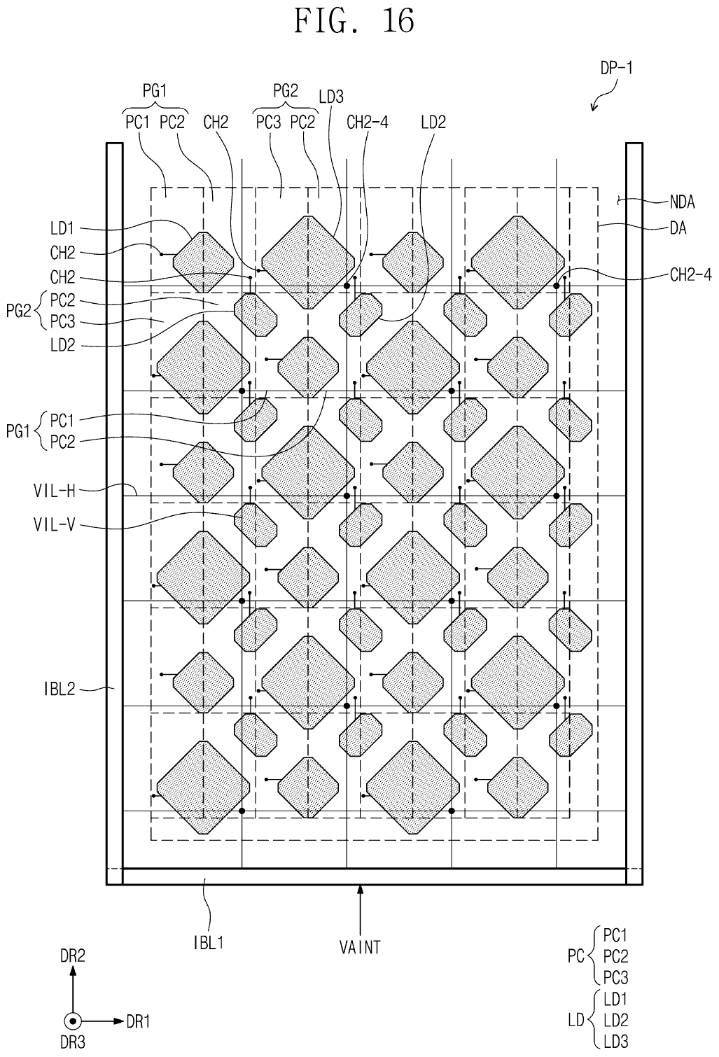

FIGS. 15, 17, and 19 may be plan views corresponding to FIG. 11, and FIGS. 16, 18, and 20 may be plan views corresponding to FIG. 12. Hereinafter, the configurations illustrated in FIGS. 15 to 20 will be described focusing on the differences from the configuration illustrated in FIGS. 11 and 12 and a repeated description of similar or identical elements may be omitted for economy of explanation.

Referring to FIG. 15, in an embodiment a display panel DP-1 may include a first power bus line PBL1 disposed in a non-display area NDA adjacent to a lower side of a display area DA (e.g., in the second direction DR2) and second power bus lines PBL2 disposed in non-display areas NDA adjacent to opposite sides of the display area DA that face away from each other in a first direction DR1. Unlike that illustrated in FIG. 11, in an embodiment the display panel DP-1 may not include a first power bus line PBL1 disposed in a non-display area NDA adjacent to an upper side of the display area DA (e.g., in the second direction DR2).

Referring to FIG. 16, the display panel DP-1 may include a first initialization bus line IBL1 disposed in the non-display area NDA adjacent to the lower side of the display area DA (e.g., in the second direction DR2) and second initialization bus lines IBL2 disposed in the non-display areas NDA adjacent to the opposite sides of the display area DA that face away from each other in the first direction DR1. Unlike that illustrated in FIG. 12, in an embodiment the display panel DP-1 may not include a first initialization bus line IBL1 disposed in the non-display area NDA adjacent to the upper side of the display area DA (e.g., in the second direction DR2).

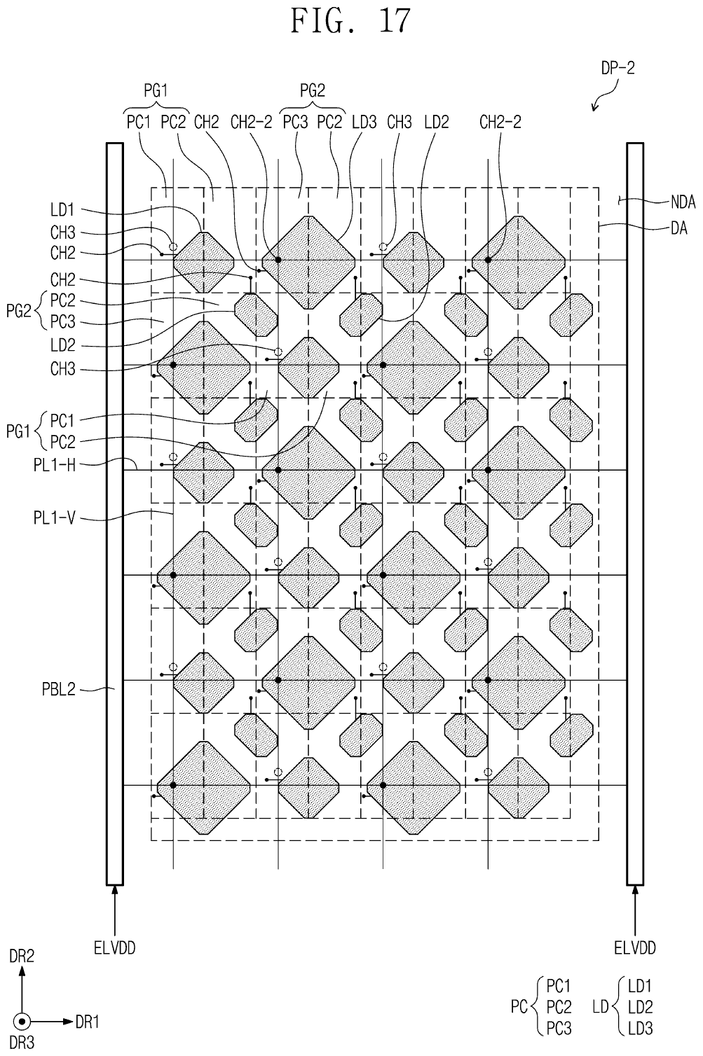

Referring to FIG. 17, a display panel DP-2 may include second power bus lines PBL2 disposed in non-display areas NDA adjacent to opposite sides of a display area DA that face away from each other in a first direction DR1. Unlike that illustrated in FIG. 11, in an embodiment the display panel DP-2 may not include first power bus lines PBL1. The first power supply voltage ELVDD may be applied to the second power bus lines PBL2.

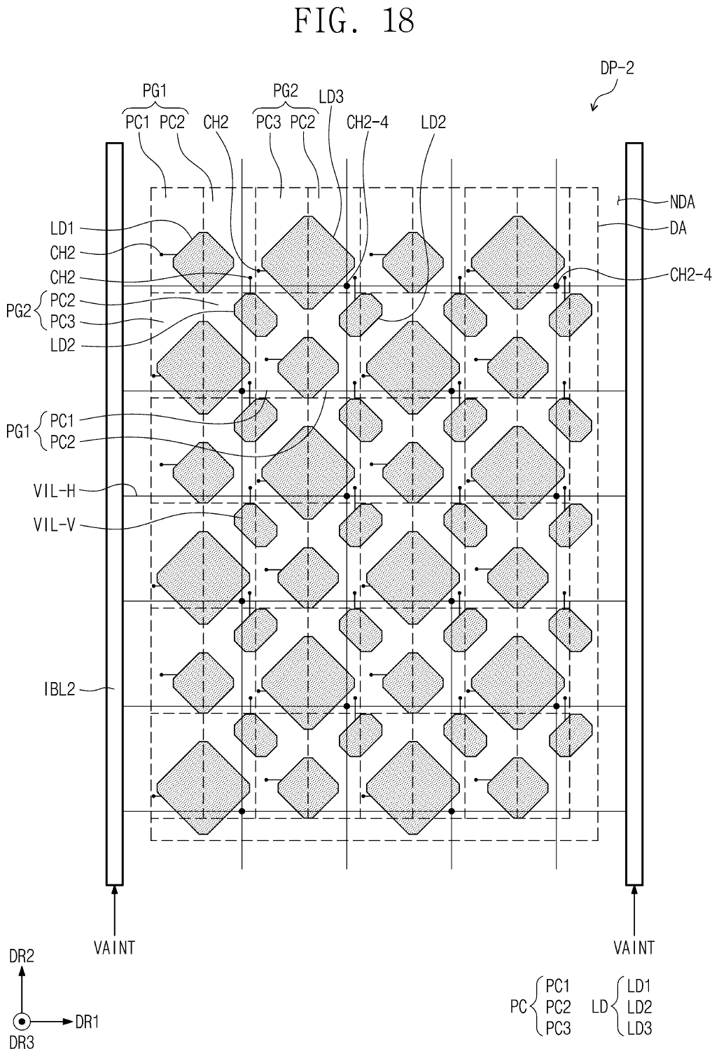

Referring to FIG. 18, the display panel DP-2 may include second initialization bus lines IBL2 disposed in the non-display areas NDA adjacent to the opposite sides of the display area DA that face away from each other in the first direction DR1. Unlike that illustrated in FIG. 12, in an embodiment the display panel DP-2 may not include first initialization bus lines IBL1. The initialization voltage may be applied to the second initialization bus lines IBL2.

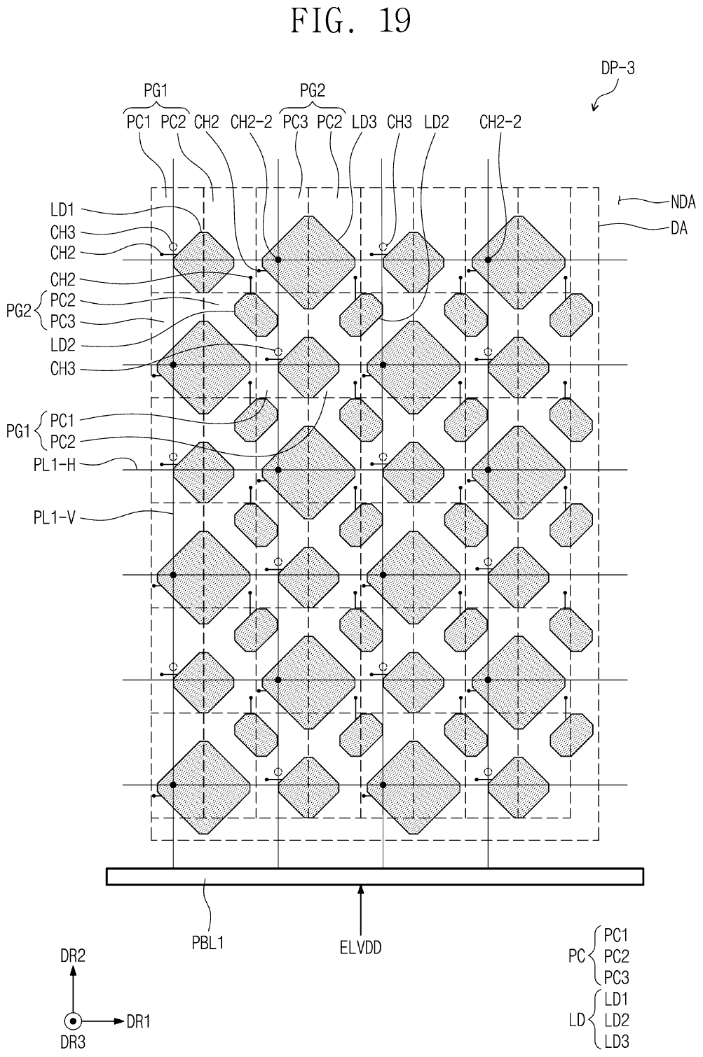

Referring to FIG. 19, a display panel DP-3 may include a first power bus line PBL1 disposed in a non-display area NDA adjacent to a lower side of a display area DA (e.g., in the second direction DR2). Unlike that illustrated in FIG. 11, in an embodiment the display panel DP-3 may not include a first power bus line PBL1 disposed in a non-display area NDA adjacent to an upper side of the display area DA (e.g., in the second direction DR2) and second power bus lines PBL2.

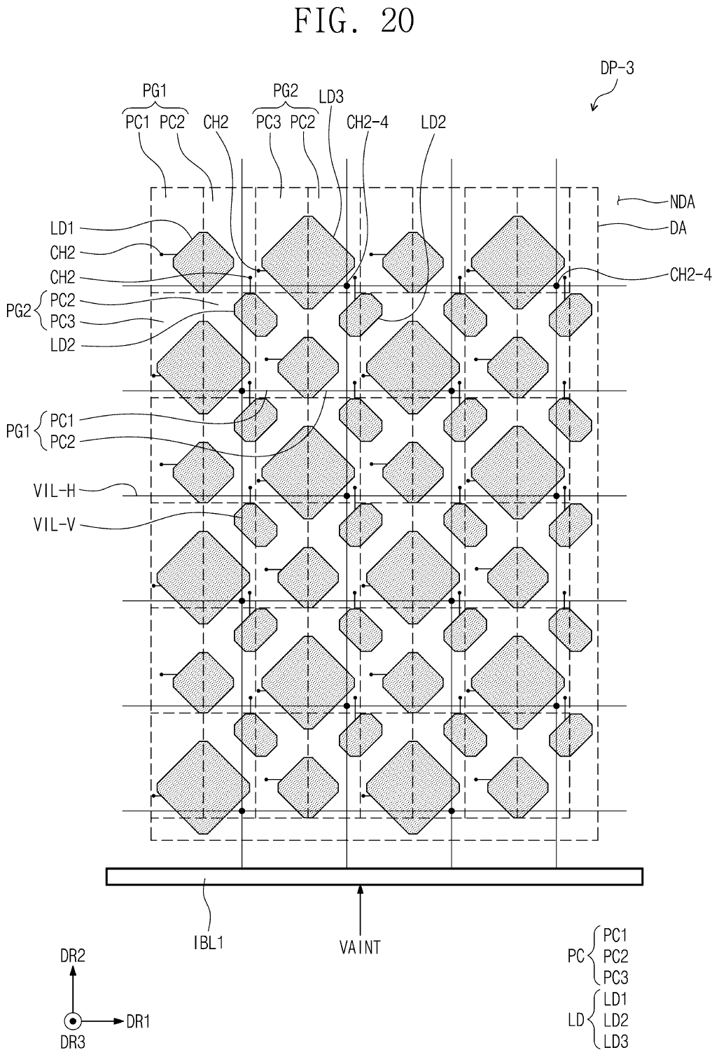

Referring to FIG. 20, the display panel DP-3 may include a first initialization bus line IBL1 disposed in the non-display area NDA adjacent to the lower side of the display area DA (e.g., in the second direction DR2). Unlike that illustrated in FIG. 12, in an embodiment the display panel DP-3 may not include a first initialization bus line IBL1 disposed in the non-display area NDA adjacent to the upper side of the display area DA (e.g., in the second direction DR2) and second initialization bus lines IBL2.

According to embodiments of the present disclosure, the power line may include the vertical power lines and the horizontal power lines, and the vertical power lines and the horizontal power lines may cross one another to form the mesh shape and may be electrically connected with one another. Accordingly, the line resistance of the power line may be decreased, and thus the first power supply voltage, which is a drive voltage, may be more stably applied to the pixels.

While the present disclosure has been described with reference to non-limiting embodiments thereof, it will be apparent to those of ordinary skill in the art that various changes and modifications may be made thereto without departing from the spirit and scope of the present disclosure.

What is claimed is:

1. A display device comprising:
a plurality of pixels; and
a power line connected to the plurality of pixels,
wherein the power line includes:
a plurality of horizontal power lines extending in a first direction and arranged in a second direction crossing the first direction; and
a plurality of vertical power lines extending in the second direction and arranged in the first direction, the plurality of vertical power lines crossing the plurality of horizontal power lines when viewed from above a plane, and
wherein the plurality of horizontal power lines is alternately connected to two adjacent vertical power lines of the plurality of vertical power lines.

2. The display device of claim 1, wherein the plurality of vertical power lines is alternately connected to two adjacent horizontal power lines of the plurality of horizontal power lines.

3. The display device of claim 1, wherein odd-numbered horizontal power lines of the plurality of horizontal power lines are connected to even-numbered vertical power lines of the plurality of vertical power lines.

4. The display device of claim 3, wherein even-numbered horizontal power lines of the plurality of horizontal power lines are connected to odd-numbered vertical power lines of the plurality of vertical power lines.

5. The display device of claim 4, wherein the odd-numbered horizontal power lines of the plurality of horizontal power lines are not connected to the odd-numbered vertical power lines of the plurality of vertical power lines.

6. The display device of claim 4, wherein the even-numbered horizontal power lines of the plurality of horizontal power lines are not connected to the even-numbered vertical power lines of the plurality of vertical power lines.

7. The display device of claim 1, wherein the plurality of vertical power lines is disposed in a different layer than the plurality of horizontal power lines.

8. The display device of claim 7, wherein the layer that the plurality of vertical power lines is disposed in is above a layer that the plurality of horizontal power lines is disposed in.

9. The display device of claim 1, further comprising:
a first power bus line extending in the first direction and connected to the plurality of vertical power lines.

10. The display device of claim 8, further comprising:
a second power bus line extending in the second direction and connected to the plurality of horizontal power lines.

11. The display device of claim 1, further comprising an initialization line connected to the plurality of pixels,
wherein the initialization line includes:
a plurality of horizontal initialization lines extending in the first direction and arranged in the second direction; and
a plurality of vertical initialization lines extending in the second direction and arranged in the first direction, the plurality of vertical initialization lines crossing the plurality of horizontal initialization lines when viewed from above the plane, and
wherein the plurality of horizontal initialization lines is alternately connected to two adjacent vertical initialization lines of the plurality of vertical initialization lines, and the plurality of vertical initialization lines is alternately connected to two adjacent horizontal initialization lines of the plurality of horizontal initialization lines.

12. The display device of claim 11, wherein:
odd-numbered horizontal initialization lines of the plurality of horizontal initialization lines are connected to even-numbered vertical initialization lines of the plurality of vertical initialization lines; and
even-numbered horizontal initialization lines of the plurality of horizontal initialization lines are connected to odd-numbered vertical initialization lines of the plurality of vertical initialization lines.

13. The display device of claim 12, wherein:
the odd-numbered horizontal initialization lines of the plurality of horizontal initialization lines are not connected to the odd-numbered vertical initialization lines of the plurality of vertical initialization lines; and
the even-numbered horizontal initialization lines of the plurality of horizontal initialization lines are not connected to the even-numbered vertical initialization lines of the plurality of vertical initialization lines.

14. The display device of claim 11, wherein:
a k-th vertical power line of the plurality of vertical power lines and a k-th vertical initialization line of the plurality of vertical initialization lines are adjacent to each other in the first direction; and
k is a natural number.

15. The display device of claim 14, wherein a portion of the k-th vertical power line of the plurality of vertical power lines and a portion of the k-th vertical initialization line of the plurality of vertical initialization lines have shapes symmetrical to each other.

16. The display device of claim 1, wherein each of the plurality of pixels includes:
a pixel circuit; and
a light emitting element connected to the pixel circuit,
wherein anodes of the light emitting elements of the plurality of pixels are integral to each other to define a first electrode,
wherein the first electrode is connected to the plurality of vertical power lines, and
wherein connection points between the first electrode and the plurality of vertical power lines are adjacent to intersections of odd-numbered horizontal power lines of the plurality of horizontal power lines and odd-numbered vertical power lines of the plurality of vertical power lines.

17. The display device of claim 16, wherein the pixel circuits of the plurality of pixels include:
a plurality of first pixel circuits connected to red light emitting elements, respectively;
a plurality of second pixel circuits connected to green light emitting elements, respectively; and
a plurality of third pixel circuits connected to blue light emitting elements, respectively,
wherein the pixel circuits are grouped into first pixel circuit groups and second pixel circuit groups alternately arranged in the first direction and the second direction,
wherein each of the first pixel circuit groups includes a first pixel circuit of the plurality of first pixel circuits and a second pixel circuit of the plurality of second pixel circuits arranged in the first direction,
wherein each of the second pixel circuit groups includes a third pixel circuit of the plurality of third pixel circuits and a second pixel circuit of the plurality of second pixel circuits arranged in the first direction, and
wherein connection points between the plurality of vertical power lines and the plurality of horizontal power lines overlap the second pixel circuit groups.

18. A display device comprising:
a plurality of pixels; and
a power line connected to the plurality of pixels,
wherein the power line includes:
a plurality of horizontal power lines extending in a first direction and arranged in a second direction crossing the first direction; and
a plurality of vertical power lines extending in the second direction and arranged in the first direction, the plurality of vertical power lines crossing the plurality of horizontal power lines when viewed from above a plane, and
wherein odd-numbered horizontal power lines of the plurality of horizontal power lines are connected to even-numbered vertical power lines of the plurality of vertical power lines, and even-numbered horizontal power lines of the plurality of horizontal power lines are connected to odd-numbered vertical power lines of the plurality of vertical power lines.

19. The display device of claim 18, wherein the odd-numbered horizontal power lines of the plurality of horizontal power lines are not connected to the odd-numbered vertical power lines of the plurality of vertical power lines, and the even-numbered horizontal power lines of the plurality of horizontal power lines are not connected to the even-numbered vertical power lines of the plurality of vertical power lines.

20. An electronic device for providing an image comprising:
a display device comprising:
a plurality of pixels; and
a power line connected to the plurality of pixels,
wherein the power line includes:
a plurality of horizontal power lines extending in a first direction and arranged in a second direction crossing the first direction;
a plurality of vertical power lines extending in the second direction and arranged in the first direction, the plurality of vertical power lines crossing the plurality of horizontal power lines when viewed from above a plane,
wherein the plurality of horizontal power lines is alternately connected to two adjacent vertical power lines of the plurality of vertical power lines, and
the plurality of vertical power lines is alternately connected to two adjacent horizontal power lines of the plurality of horizontal power lines.
